(19) United States
(12) Patent Application Publication
(10) Pub. No.: US 2007/0248746 A1
(43) Pub. Date: Oct. 25, 2007

(54) MANUFACTURING METHOD OF ORGANIC ELECTROLUMINESCENCE ELEMENT

(76) Inventors: Norihito ITO, Tokyo-to (JP); Yasuhiro IIZUMI, Tokyo-to (JP)

Correspondence Address: LADAS & PARRY LLP, 224 SOUTH MICHIGAN AVENUE, SUITE 1600, CHICAGO, IL, 60604, US

(21) Appl. No.: 11/736,667

(22) Filed: Apr. 18, 2007

(30) Foreign Application Priority Data
Apr. 20, 2006 (JP) 2006-116745

(51) Int. Cl. B05D 5/06

(52) U.S. Cl. 427/64

(57) ABSTRACT

A main object is to provide a manufacturing method of an organic EL element having excellent light emission characteristics, and capable of facilitating the organic EL layer patterning operation and obtaining preferable wettability change. To attain the object, the present invention provides a manufacturing method of an organic EL element comprising: a charge injecting and transporting layer forming step of forming a charge injecting and transporting layer containing a material having a liquid repellent functional group so as to have the wettability change by the action of the photocatalyst accompanied by the energy irradiation on a substrate with an electrode layer formed; a wettability changed pattern forming step of forming a wettability changed pattern with the wettability of the charge injecting and transporting layer surface changed by the energy irradiation in pattern after disposing the photocatalyst processing layer substrate, in which the photocatalyst processing layer containing at least a photocatalyst is formed on a base member, with a gap capable of providing the action of the photocatalyst accompanied by the energy irradiation to the charge injecting and transporting layer; and an organic EL layer forming step of forming an organic EL layer, which includes at least a light emitting layer, on the wettability changed pattern.

### BACKGROUND OF THE INVENTION

1. Field of the Invention

The present invention relates to a manufacturing method of an EL element of patterning an organic electroluminescence (i.e., EL) layer using a layer whose wettability changes by the action of a photocatalyst accompanied by the energy irradiation.

2. Description of the Related Art

EL elements are for coupling a hole and an electron, injected from two electrodes facing each other, in a light emitting layer for exciting a fluorescent substance in the light emitting layer through its energy to emit a light beam of a color corresponding to the fluorescent substance, and as such gaining attention as planer display elements of a self light emission type. In particular, since organic EL displays using organic materials as light emitting materials have a high light emitting efficiency capable of realizing a high brightness light emission with an applied voltage of less than 10 V and allow the light emission in a simple element structure, application to the inexpensive simple displays, such as advertisements of specific patterns by light emission display is expected.

In general, when manufacturing a display using an EL element, patterning of the organic EL layer or other members is carried out. As methods for patterning the organic EL layer, various patterning methods have been proposed: a method of depositing a light emitting material via a shadow mask, a method of coating the layer separately by inkjet, a method of destroying a specific light emitting pigment by the ultraviolet ray exposure, and a screen printing method. Moreover, according to the method of separately coating by ink jet, a technique of forming a pattern-like partition wall (bank) and treating the partition wall surface with an ink repellent process has been proposed to obtain a highly precise minute pattern, (see for example Japanese Patent Nos. 3,601,716 and 3,646,510). Furthermore, as a method for patterning an organic EL layer, a method of using a photocatalyst that enables the highly precise pattern formation has also been proposed (see for example Japanese Patent Application Laid Open (JP-A) Nos. 2001-257073 and 2002-231446).

The method using the photocatalyst utilizes the wettability change of the layer containing the photocatalyst caused by the action of the photocatalyst upon the energy irradiation to the photocatalyst-containing layer. In other words, the organic EL layer can be formed in pattern by utilizing the pattern caused by the wettability difference. Accordingly, such method of patterning an organic EL layer using a photocatalyst is useful in terms of dramatically reducing the labor required for patterning because a pattern of wettability difference can be formed only by the energy irradiation.

However, in the method of patterning an organic EL layer using a photocatalyst, the surface state of the layer containing the photocatalyst may become rough because the photocatalyst such as titanium oxide is granular shape. Accordingly, obstacles present between the light emitting layer and the layer containing the photocatalyst become large to disturb the charge transfer. As a recult, a problematic decline in the light emission characteristics maybe caused. Moreover, the roughness of the surface state of the photocatalyst-containing layer may generate a problematic film thickness irregularity in a light emitting layer that has a relatively thin thickness and a problematic short circuit between electrodes.

For solving these problems, a method of forming a pattern of a wettability difference by using a substrate having a layer containing a photocatalyst is disclosed (see for example JP-A No. 2004-71286). In the method, a layer whose wettability is to be changed by the action of the photocatalyst accompanied by the energy irradiation and a layer containing the photocatalyst are disposed to face each other, and energy is directed thereto to change the wettability of the layer surface. JP-A No. 2004-71286 also discloses a method for patterning an organic EL layer using a charge injecting and transporting layer whose wettability changes by the action of the photocatalyst accompanied by the energy irradiation.

The charge injecting and transporting layer mentioned above contains a binder such as organopolysiloxane and a photocatalyst, or a material generally used for a charge injecting and transporting layer such as polyethylene dioxythiophene/polystyrene sulfonate (PEDOT-PSS). In the former case, improvement of the surface state roughness can be expected because the charge injecting and transporting layer contains a photocatalyst. In the latter case, a good wettability change may not be obtained because the charge injecting and transporting layer contains the material used commonly as a charge injecting and transporting layer.

### SUMMARY OF THE INVENTION

The present invention has been achieved in view of the above-mentioned problems. A main object is to provide a manufacturing method of an organic EL element having excellent light emission characteristics that can facilitate the organic EL layer patterning and allows good wettability change.

To attain the object, the present invention provides a manufacturing method of an organic EL element comprising: a charge injecting and transporting layer forming step of forming, on a substrate with an electrode layer formed, a charge injecting and transporting layer containing a material having a liquid repellent functional group so as to have a wettability change by an action of a photocatalyst accompanied by energy irradiation; a wettability changed pattern forming step of forming a wettability changed pattern with wettability changed on a surface of the charge injecting and transporting layer by the energy irradiation in pattern after disposing a photocatalyst processing layer substrate, in which a photocatalyst processing layer containing at least a photocatalyst is formed on a base member, with a gap capable of providing the action of the photocatalyst accompanied by the energy irradiation to the charge injecting and transporting layer; and an organic EL layer forming step of forming an organic EL layer, which includes at least a light emitting layer, on the wettability changed pattern.

In the present invention, since the charge injecting and transporting layer contains the material having the liquid repellent functional group, a large difference in the wettability can be generated between the portion with the energy irradiation and the portion without the irradiation by the oxidization or decomposition of the liquid repellent functional group and the other organic groups by the action of the photocatalyst. Moreover, the photocatalyst is contained in the photocatalyst processing layer and the photocatalyst processing layer substrate having the photocatalyst processing layer is to be detached from the charge injecting and transporting layer after the wettability changed pattern forming step. Accordingly, the photocatalyst is not contained in the charge injecting and transporting layer. Therefore, the light emission characteristics can be improved by reducing the obstacles at the interface between the charge injecting and transporting layer and the organic EL layer, and the short circuit between the electrodes can be prevented. Furthermore, since the wettability changed pattern is formed by irradiating the energy via the photocatalyst processing layer to the charge injecting and transporting layer whose wettability changes by the action of the photocatalyst accompanied by the energy irradiation, the organic EL layer can be formed easily in pattern by utilizing the wettability difference in the wettability changed pattern.

In the present invention, the material having the liquid repellent functional group may be a liquid repellent material, and the charge injecting and transporting layer may further contain a charge injecting and transporting material having the charge injecting and transporting properties. The material having the liquid repellent functional group may be a single material having a portion with the charge injecting and transporting properties and a portion with a liquid repellent functional group.

In the present invention, the liquid repellent functional group preferably contains fluorine. This is because fluorine has a very low surface energy and it can improve liquid repellency of the charge injecting and transporting layer.

The present invention further provides a manufacturing method of an organic EL element comprising: a charge injecting and transporting layer forming step of forming a charge injecting and transporting layer on a substrate with an electrode layer formed; a liquid repellent process step of processing a surface of the charge injecting and transporting layer to be liquid repellent; a wettability changed pattern forming step of forming a wettability changed pattern with wettability changed on the surface of the charge injecting and transporting layer by energy irradiation in pattern after disposing a photocatalyst processing layer substrate, in which a photocatalyst processing layer containing at least a photocatalyst is formed on a base member, with a gap capable of providing an action of the photocatalyst accompanied by the energy irradiation to the charge injecting and transporting layer with the liquid repellent process applied; and an organic electroluminescence layer forming step of forming an organic EL layer, which includes at least alight emitting layer, on the wettability changed pattern.

In the present invention, since the liquid repellent process step for having the surface of the charge injecting and transporting layer liquid repellent is carried out before the wettability changed pattern forming step, a large difference in the wettability can be generated between the portion with the energy irradiation and the portion without the irradiation. Further, as mentioned above, the photocatalyst processing layer substrate having the photocatalyst processing layer containing the photocatalyst is to be detached from the charge injecting and transporting layer after the wettability changed pattern forming step. Thus, decline in the light emission characteristics or generation of the short circuit between the electrodes that are caused by the surface state roughness of the layer deriving from the photocatalyst can be avoided. Furthermore, the wettability changed pattern can be formed on the charge injecting and transporting layer surface by the energy irradiation via the photocatalyst processing layer. Therefore, the organic EL layer can be formed easily in pattern, utilizing the wettability changed pattern.

In the above-mentioned invention, the above-mentioned liquid repellent process step may be a step of inducing plasma to the charge injecting and transporting layer using a fluorine compound as introduction gas. Since the plasma is induced using the fluorine compound as the introduction gas, fluorine can be introduced into the organic material in the charge injecting and transporting layer so as to provide the liquid repellent properties to the charge injecting and transporting layer. Moreover, since the energy is irradiated via the photocatalyst processing layer, the fluorine introduced into the organic material in the charge injecting and transporting layer can be removed by the action of the photo catalyst. Thereby, wettability difference can be generated between the portion with the energy irradiation and the portion without the irradiation.

Moreover, in the present invention, it is preferable that the charge injecting and transporting layer is a hole injecting and transporting layer. This is because, in general, in the production process of an organic EL element, the layers can be laminated stably by laminating from the anode side.

In the present invention, an insulation layer forming step of forming an insulation layer, for reflecting or absorbing energy line to be irradiated in the wettability changed pattern forming step, between patterns of the electrode layer on the substrate with the electrode layer formed in pattern may be carried out before the charge injecting and transporting layer forming step. In a case such insulation layer is formed, the energy can be irradiated to the entire surface from the substrate side without using a photo mask or a laser beam in the wettability changed pattern forming step.

Using of the material having a liquid repellent functional group for the charge injecting and transporting layer or applying of the liquid repellent process to the charge injecting and transporting layer enables the present invention to achieve the effect of obtaining a good wettability change. Moreover, since the photocatalyst is contained in the photocatalyst processing layer of the photocatalyst processing layer substrate to be detached after the wettability changed pattern forming step and not contained in the charge injecting and transporting layer, the smoothness of the charge injecting and transporting layer can be improved so that the effect of obtaining good light emission characteristics can be achieved.

### BRIEF DESCRIPTION OF THE DRAWINGS

FIGS. 1A to 1E is a process drawing showing an example of the manufacturing method of an organic EL element of the present invention.

FIGS. 2A and 2B are each a schematic cross-sectional view showing an example of a photocatalyst processing layer substrate used for the present invention.

FIG. 3 is a schematic cross-sectional view showing another example of a photocatalyst processing layer substrate used for the present invention.

FIG. 4 is a schematic cross-sectional view showing yet another example of a photocatalyst processing layer substrate used for the present invention.

FIGS. 5A to 5F is a process drawing showing another example of the manufacturing method of an organic EL element of the present invention.

FIGS. 6A to 6F is a process drawing showing yet another example of the manufacturing method of an organic EL element of the present invention.

### DESCRIPTION OF THE PREFERRED EMBODIMENTS

Hereinafter, the manufacturing method of an organic EL element of the present invention will be explained in detail.

The manufacturing method of an organic EL element of the present invention can be classified into two embodiments. A first embodiment is to have the wettability change of the material contained in the charge injecting and transporting layer by the action of the photocatalyst accompanied by the energy irradiation. A second embodiment is to have the liquid repellent properties by applying the liquid repellent process to the charge injecting and transporting layer and to have the wettability change by the action of the photocatalyst accompanied by the energy irradiation.

Hereafter, the embodiments will be explained.

### I. First Embodiment

First embodiment of the manufacturing method of an organic EL element comprises: a charge injecting and transporting layer forming step of forming, on a substrate with an electrode layer formed, a charge injecting and transporting layer containing a material having a liquid repellent functional group so as to have a wettability change by an action of a photocatalyst accompanied by energy irradiation; a wettability changed pattern forming step of forming a wettability changed pattern with wettability changed on a surface of the charge injecting and transporting layer by the energy irradiation in pattern after disposing a photocatalyst processing layer substrate, in which a photocatalyst processing layer containing at least a photocatalyst is formed on a base member, with a gap capable of providing the action of the photocatalyst accompanied by the energy irradiation to the charge injecting and transporting layer; and an organic electroluminescence layer forming step of forming an organic EL layer, which includes at least a light emitting layer, on the wettability changed pattern.

The manufacturing method of an organic EL element of this embodiment will be explained with reference to the drawings.

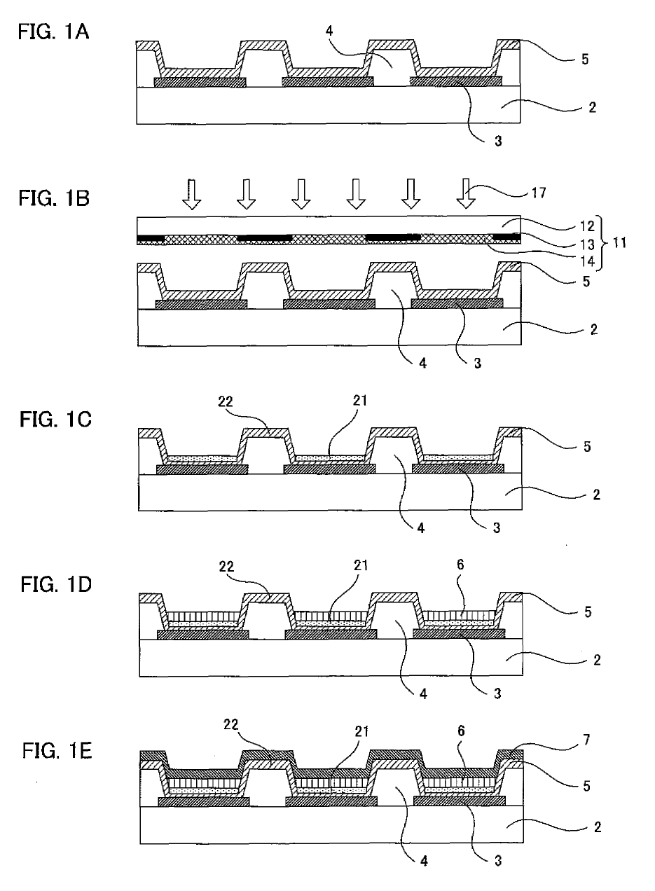

FIGS. 1A to 1E is a process drawing showing an example of the manufacturing method of an organic EL element of this embodiment. First, an electrode layer 3 is formed in pattern on a substrate 2, an insulation layer 4 is formed between the pattern of the electrode layer 3, and a charge injecting and transporting layer 5 is formed on the electrode layer 3 and the insulation layer 4 (FIG. 1A, charge injecting and transporting layer forming step).

Then, as shown in FIG. 1B, a photocatalyst processing layer substrate 11 having a base member 12, a light shielding part 13 formed in pattern on the base member 12, and a photocatalyst processing layer 14 formed on the base member 12 so as to cover the light shielding part 13 is prepared. Then, the photocatalyst processing layer 14 of the photocatalyst processing layer substrate 11 and the charge injecting and transporting layer 5 are disposed to face each other, and an ultraviolet ray 17 is irradiated. Through the ultraviolet ray 17 irradiation, as shown in FIG. 1C, the wettability is changed so as to have the contact angle with respect to a liquid lowered in the ultraviolet ray irradiated portion of the charge injecting and transporting layer 5 by the action of the photocatalyst contained in the photocatalyst processing layer 14. The region in which the wettability is changed so as to have the contact angle with respect to a liquid lowered is referred to as a lyophilic region 21. The wettability is not changed in the ultraviolet ray unirradiated portion. The region in which the wettability is not changed is referred to as a liquid repellent region 22. Subsequently, the photocatalyst processing layer substrate 11 is detached from the charge injecting and transporting layer 5. Thereby, a wettability changed pattern comprising the lyophilic region 21 and the liquid repellent region 22 can be formed on the charge injecting and transporting layer 5 surface. FIGS. 1B and 1C show a wettability changed pattern forming step.

The charge injecting and transporting layer 5 has the wettability change by the action of the photocatalyst accompanied by the energy irradiation. The lyophilic region 21 as the ultraviolet ray irradiated portion and the liquid repellent region 22 as the ultraviolet ray unirradiated portion have the wettability difference.

Next, utilizing the wettability difference, organic EL layer forming coating solution is applied on the wettability changed pattern having the lyophilic region 21 and the liquid repellent region 22, and an organic EL layer 6 is formed only on the lyophilic region 21 (FIG. 1D, organic EL layer forming step).

Then, a counter electrode layer 7 is formed on the organic EL layer 6 (FIG. 1E). At the time, in the case the counter electrode layer 7 is a transparent electrode, a top emission type organic EL element can be obtained, and in the case the electrode layer 3 is a transparent electrode, a bottom emission type organic EL element can be obtained.

In this embodiment, since the energy is irradiated, via the photocatalyst processing layer containing the photocatalyst, to the charge injecting and transporting layer to have the wettability change by the action of the photocatalyst accompanied by the energy irradiation, a wettability changed pattern is formed by the wettability difference on the charge injecting and transporting layer surface. The organic EL layer is patterned, by utilizing this wettability changed pattern. Therefore, the organic EL layer can be patterned easily without a complicated patterning step or expensive vacuum equipment.

Moreover, in this embodiment, by the pattern irradiation of energy to the charge injecting and transporting layer via the photocatalyst processing layer which contains the photocatalyst, the wettability can be changed by the action of the photocatalyst with respect to the charge injecting and transporting layer which does not contain the photocatalyst. Furthermore, since the photocatalyst processing layer substrate having the photocatalyst processing layer is detached from the charge injecting and transporting layer after formation of the wettability changed pattern on the charge injecting and transporting layer, the organic EL element itself does not contain the photocatalyst. That is, the photocatalyst is contained in the photocatalyst processing layer and it is not contained in the charge injecting and transporting layer. Therefore, the smoothness of the charge injecting and transporting layer can be improved so that the obstacles present at the interface of the charge injecting transporting layer and the organic EL layer can be reduced. Thereby, the light emission characteristics can be improved by reducing the driving voltage, improving the light emission intensity and the light emission efficiency. Moreover, the short circuit between the electrodes can also be prevented.

Furthermore, in this embodiment, since the charge injecting and transporting layer contains the material having a liquid repellent functional group, a large wettability difference can be generated between the portion with the energy irradiation and without the irradiation. This is because the wettability of the energy irradiated portion changes through oxidization or decomposition of the liquid repellent functional group and the other organic groups by the action of the photocatalyst in the photocatalyst processing layer. Accordingly, adhesion of the organic EL layer forming coating solution onto the liquid repellent region, the energy unirradiated portion, can be prevented and adhesion occurs only onto the lyophilic region, the energy irradiated portion. Therefore, a highly precise organic EL layer pattern can be formed.

Moreover, the charge injecting and transporting function of the charge injecting and transporting layer may be improved by the energy irradiation to the charge injecting and transporting layer. Therefore, this embodiment is particularly useful for patterning of the organic EL layer.

Hereafter, each step of the manufacturing method of an organic EL element will be explained.

### 1. Charge Injecting and Transporting Layer Forming Step

The charge injecting and transporting layer forming step in this embodiment is a step of forming a charge injecting and transporting layer, on a substrate with an electrode layer formed, in which the charge injecting and transporting layer contains a material having a liquid repellent functional group and whose wettability changed by the action of the photocatalyst accompanied by the energy irradiation.

Hereafter, the charge injecting and transporting layer, the electrode layer and the substrate will be explained.

### (1) Charge Injecting and Transporting Layer

The charge injecting and transporting layer in this embodiment contains a material having a liquid repellent functional group and has the wettability change by the action of the photocatalyst accompanied by the energy irradiation.

In the present invention, the charge injecting and transporting layer has a function of stably transporting the charge from the electrode layer to the organic EL layer. Since the charge injecting and transporting layer is provided between the organic EL layer containing at least a light emitting layer and the electrode layer, the charge injection to the light emitting layer can be stabilized and improve the light emission efficiency can be improved.

As the charge injecting and transporting layer, there are a hole injecting and transporting layer for stably injecting and transporting the hole into the light emitting layer, and an electron injecting and transporting layer for stably injecting and transporting the electron into the light emitting layer. In general, since organic EL elements can be produced stably by laminating from an anode side at the time of prediction, it is preferable that the electrode layer is an anode and the charge injecting and transporting layer is a hole injecting and transporting layer.

Hereafter, the hole injecting and transporting layer and the electron injecting and transporting layer will be explained separately.

(i) Hole Injecting and Transporting Layer

The hole injecting and transporting layer in this embodiment may be: a hole injecting layer having a hole injecting function of injecting the hole injected from the anode stably into the light emitting layer; a hole transporting layer having a hole transporting function of transporting the hole injected from the anode into the light emitting layer; a lamination of the hole injecting layer and the hole transporting layer; or a single layer having both the hole injecting function and the hole transporting function.

The hole injecting and transporting layer contains a material having the liquid repellent functional group. In the case the hole injecting and transporting layer is a lamination of the hole injecting layer and the hole transporting layer, they are laminated in the order of the hole injecting layer and the hole transporting layer. Accordingly, only the hole transporting layer may contain a material having the liquid repellent functional group.

As the hole injecting and transporting layer, there are two preferable aspects. A first aspect of the hole injecting and transporting layer contains: a hole injecting and transporting material having a hole injecting and transporting properties, and a liquid repellent material having a liquid repellent functional group. A second aspect of the hole injecting and transporting layer contains a single material having: a portion with the hole injecting and transporting properties, and a portion having a liquid repellent functional group. Hereafter, each embodiment will be explained.

### (First Aspect)

For the hole injecting and transporting layer of the first aspect, a hole injecting and transporting material having a hole injecting and transporting properties and a liquid repellent material having a liquid repellent functional group are used.

The hole injecting and transporting material is not particularly limited as long as it is a material capable of stably transporting the hole injected from the anode into the light emitting layer. The material can be selected optionally depending on the kind of the above-mentioned hole injecting and transporting layer. The hole injecting and transporting material may be: a hole injecting material having a hole injecting properties; or a hole transporting material having hole transporting properties, or a material having both hole injecting properties and hole transporting properties.

In addition to the compounds presented for the light emitting material for the light emitting layer to be mentioned later, examples of the hole injecting and transporting material are: oxides such as vanadium oxide, molybdenum oxide, ruthenium oxide, aluminum oxide; and phenyl amines, star burst type amines, phthalocyanines, amorphous carbon, polyaniline, polythiophene, and polyphenylene vinylene derivatives. Conductive polymers such as polyaniline, polythiophene, and polyphenylene vinylene derivatives may be doped with acid. As specific examples, 4,4′-bis(N-(1-naphthyl)-N-phenyl-amino]biphenyl (α-NPD), 4,4′,4′″-tris(N,N-diphenyl-amino)-triphenylamine (TDATA), 4,4′,4″-tris(3-methyl phenyl phenyl amino)triphenyl amine (MTDATA), polyvinyl carbazole (PVCz), or poly(3,4-ethylene dioxythiophene)-polystyrene sulfonic acid (PEDOT-PSS) can be presented.

In particular, it is preferable that the hole injecting and transporting material have a relatively high resistance because the cross-talk may be generated with a too low resistance. Among those mentioned above, as the high resistance hole injecting and transporting material, poly(3,4 ethylene dioxythiophene)/polystyrene sulfonic acid (PEDOT/PSS), or the like can be used preferably. As a commercially available product of an aqueous solution of the high resistnace PEDOT/PSS, Baytron P CH-800 produced by H. C. Stark Inc. can be presented.

Moreover, the liquid repellent material may be one having a liquid repellent functional group. The material is preferably a material whose wettability changes by the action of the photocatalyst in the photocatalyst processing layer accompanied by the energy irradiation, and having a principal chain to be hardly deteriorated or decomposed by the action of the photocatalyst.

As the liquid repellent functional group, for example, a group containing fluorine, a long chain alkyl group, a vinyl group, an amino group, a phenyl group, an epoxy group, an alkoxyl group, or an acetyl group can be presented. In particular, it is preferable that the liquid repellent functional group is the group containing fluorine or the long chain alkyl group. It is preferable that the number of carbon atoms of the long chain alkyl group is in the range of 9 to 20. A particularly preferable long chain alkyl group is an octadecyl group.

Examples of the material with a principal chain to be hardly deteriorated or decomposed by the action of the photocatalyst are (1) an organopolysiloxane which exhibits a large strength and can be obtained by hydrolyzing and polycondensing chloro or alkoxysilane by sol-gel reaction, and (2) an organopolysiloxane obtained by crosslinking a reactive silicone excellent in water repellency or oil repellency.

In the case (1), the liquid repellent material is preferably an organopolysiloxane as a hydrolyzed condensation product or a co-hydrolyzed condensation product of one or two or more kinds of silicon compounds represented by the general formula:

YₙSiX₍₄₋ₙ₎

(Here, Y is an alkyl group, a fluoroalkyl group, a vinyl group, an amino group, a phenyl group, or an epoxy group; X is an alkoxyl group, an acetyl group or a halogen; and n is an integer from 0 to 3). Here, the number of atoms of the group represented by Y is preferably in a range of 1 to 20. Moreover, the alkoxyl group represented by X is preferably a methoxy group, an ethoxy group, a propoxy group, or a butoxy group. Specific examples of the silicon compounds are those disclosed in JP-A No. 2000-249821.

It is particularly preferable that the liquid repellent material is an organopolysiloxane containing the fluoroalkyl group. As the organopolysiloxane containing the fluoroalkyl group, specifically, a hydrolyzed condensation product or a co-hydrolyzed condensation product of one or two or more kinds of the fluoroalkyl silanes disclosed in JP-A No. 2000-249821 can be presented, and those commonly known as a fluorine based silane coupling agent can be used.

Since the polysiloxanes containing the fluoroalkyl group as mentioned above are used as the liquid repellent material, the liquid repellent properties can be dramatically improved in the portion without the energy irradiation on the hole injecting and transporting layer surface. Accordingly, film formation of the organic EL layer can be prevented in the liquid repellent region which is the energy unirradiated portion, and thus the organic EL layer can be formed only in the lyophilic region which is the energy irradiated portion.

Inclusion of the organopolysiloxane having the fluoroalkyl group in the hole injecting and transporting layer can be confirmed by the X-ray photoelectron spectrometry, the Rutherford back scattering spectrometry, nuclear magnetic resonance spectrometry, or the mass spectrometry.

Moreover, as the reactive silicone (2) used for the liquid repellent material, compounds having a skeleton represented by the following chemical formula (1) can be presented.

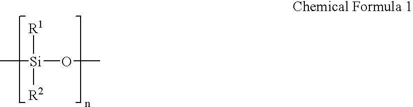

Here, n is an integer of 2 or more; R¹ and R² each are a substituted or non substituted alkyl, alkenyl, aryl or cyanoalkyl group having 1 to 10 carbon atoms, and 40% or less of the entirety based on the mole ratio is vinyl, phenyl, or halogenated phenyl. Moreover, those having R¹ and/or R² as a methyl group are preferable since the surface energy becomes the smallest, and it is preferable that a methyl group accounts for 60% or more based on the mole ratio. Moreover, at least one reactive group such as a hydroxyl group is provided in a molecular chain at the chain end or the side chain.

Moreover, together with the above-mentioned organopolysiloxane, a stable organosilicon compound with no cross-linking reaction such as dimethylpolysiloxane may be mixed in the liquid repellent material.

In this embodiment, various liquid repellent materials such as the organopolysiloxane can be used for the hole injecting and transporting layer. As mentioned, it is preferable that the liquid repellent functional group in the liquid repellent material is a group containing fluorine or a long chain alkyl group. That is, it is preferable that the hole injecting and transporting layer contains fluorine or a long chain alkyl group.

Since the fluorine has an extremely low surface energy, the surface of a substance containing much fluorine has a smaller critical surface tension. Thereby, the critical surface tension of a portion having a small fluorine content is larger than the critical surface tension of a portion having a large fluorine content. That is, the portion with a small fluorine content provides a lyophilic region with respect to the portion with a large fluorine content.

In the case the hole injecting and transporting layer contains the fluorine, it is preferable that the fluorine content of the hole injecting and transporting layer surface becomes smaller, according to the action of the photocatalyst accompanied by the energy irradiation, compared to the state before the energy irradiation. This is because such hole injecting and transporting layer allows a wettability changed pattern to be formed with a portion with a small fluorine content (lyophilic region) which is the energy irradiated portion and a portion with a large fluorine content (liquid repellent region) which is the energy unirradiated portion by the pattern irradiation of energy. Accordingly, in the case the hole injecting and transporting layer contains the fluorine, it is advantageous for the wettability changed pattern formation.

In the case the hole injecting and transporting layer contains the fluorine, with the premise that the fluorine content in the liquid repellent region having a large fluorine content which is the energy unirradiated portion is 100, it is preferable that the fluorine content in the lyophilic region with a small fluorine content which is the energy irradiated portion is 50 or less, more preferably 20 or less, and further preferably 10 or less. The above-mentioned range can generate a large wettability difference between the energy irradiated portion and the unirradiated portion. The above-mentioned values are based on the weight.

As to the fluorine content measurement, common method can be used. For example, methods capable of quantitatively measuring the surface fluorine amount such as the X-ray photo electron spectroscopy, the ESCA (electron spectroscopy for chemical analysis), a fluorescence X-ray spectroscopy, and the mass analysis can be used.

The liquid repellent material content in the hole injecting and transporting layer is not particularly limited as long as it is an amount capable of providing the liquid repellent properties to the hole injecting and transporting layer without inhibiting the transportation of the hole. Specifically, the liquid repellent material content in the hole injecting and transporting layer is preferably in the range of 0.1% by weight to 50% by weight, and more preferably in the range of 1% by weight to 20% by weight. In the case the liquid repellent material content is less than the above-mentioned range, the liquid repellent properties may not be obtained sufficiently. In the case the liquid repellent material content is more than the range, the hole transportation may be inhibited.

It is preferable that the hole injecting and transporting layer has a contact angle with respect to a liquid having a surface tension equivalent to the surface tension of the organic EL layer forming coating solution to be applied of 20° or more, more preferably 30° or more, and further preferably 40° or more. Since the energy unirradiated portion is required to have the liquid repellent properties, if the contact angle with respect to the liquid of the hole injecting and transporting layer is too small, the liquid repellent properties are not sufficient and the organic EL layer forming coating solution may be adhered also on the liquid repellent region.

The contact angle with respect to a liquid here is obtained from the results or a graph of the results of measuring (30 seconds after of dropping liquid droplets from a micro syringe) the contact angle with respect to liquids having various surface tensions using a contact angle measuring device (CA-Z type manufactured by Kyowa Interface Science, Co., Ltd). Moreover, at the time of the measurement, as the liquids having the various surface tensions, the wetting index standard solution manufactured by JUNSEI CHEMICAL CO., LTD. were used.

The film thickness of the hole injecting and transporting layer is not particularly limited as long as it is a film thickness capable of sufficiently performing its function as well as capable of forming the wettability changed pattern. Specifically, the film thickness of the hole injecting and transporting layer is in the range of 5 nm to 200 nm, and particularly preferably in the range of 10 nm to 100 nm. If the film thickness of the hole injecting and transporting layer is too thin, the wettability difference may not be provided clearly so that the wettability changed pattern formation may be difficult. Moreover, if the film thickness of the layer is too thick, the hole transportation may be inhibited.

The hole injecting and transporting layer may be formed by preparing a hole injecting and transporting layer forming coating solution by dispersing the above-mentioned hole transporting material and the liquid repellent material in a solvent as needed with other additives, and applying the hole injecting and transporting layer forming coating solution onto a substrate.

As the solvent used for the hole injecting and transporting layer forming coating solution, an alcohol based organic solvent such as ethanol and isopropanol can be used preferably.

Moreover, as the applying method for the hole injecting and transporting layer forming coating solution, common methods such as a spin coating method, a spray coating method, a dip coating method, a roll coating method, a bead coating method and a printing method can be used.

### (Second Aspect)

For the hole injecting and transporting layer of the second aspect, a single material having a portion with hole injecting and transporting properties and a portion having a liquid repellent functional group is used.

The portion having the hole injecting and transporting properties is not particularly limited as long as it can stably transport the hole injected from the anode into the light emitting layer, and to be hardly deteriorated or decomposed by the action of the photocatalyst. The portion having the hole injecting and transporting properties may have: the hole injecting properties, the hole transporting properties, or both the hole injecting properties and the hole transporting properties, and it may be selected optionally according to the kind of the above-mentioned hole injecting and transporting layer.

As the portion having the hole injecting and transporting properties, for example, a conductive polymer such as polyaniline, polythiophene, polyphenylene vinylene, and polyacetylene can be presented. These conductive polymers may be doped with acid. Specifically, poly(3,4 ethylene dioxy thiophene)/polystyrene sulfonic acid (PEDOT/PSS) can be presented. In this case, a liquid repellent functional group may be introduced in the PEDOT which is the conductive polymer, or a liquid repellent functional group may be introduced in the PSS which is the acid.

Since the liquid repellent functional group is same as described in the above-mentioned first aspect, the explanation thereof is omitted.

The amount of the liquid repellent functional group contained in a molecule is not particularly limited as long as it is an amount capable of providing the liquid repellent properties to the hole injecting and transporting layer without inhibiting the hole transportation. Specifically, the amount of the liquid repellent functional group contained in a molecule is preferably in the range of 0.1% to 50% by the mole ratio. If the amount of the liquid repellent functional group is less than the above-mentioned range, sufficient liquid repellent properties may not be obtained. Moreover, if the amount of the liquid repellent functional group is more than the range, the hole transportation may be inhibited.

As such single material having the portion with the hole injecting and transporting properties and the portion with the liquid repellent functional group, a polythiophene represented by the following chemical formula 2 with an acid such as PSS doped may be presented. As to the polythiophene with an acid doped, JP-A No. 2005-206839 may be referred to.

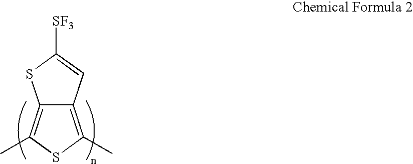

Moreover, as the single material having the portion with the hole injecting and transporting properties and the portion with the liquid repellent functional group, a Nafion solution containing a perfluorosulfonic acid represented by the following chemical formula 3 (Sigma-Aldrich Japan K.K.), or a conductive polymer such as a PEDOT with the perfluorosulfonic acid of the Nafion dispersion doped can be presented.

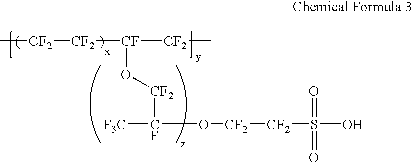

In particular, it is preferable that the single material having the portion with the hole injecting and transporting properties and the portion with the liquid repellent functional group has a relatively high resistance. This is because if the resistance is too low, the cross-talk may be generated. For example in the case of a conductive polymer with acid doped, the resistance can be adjusted by changing the mixing ratio of the conductive polymer and the acid.

The contact angle with a liquid of the hole injecting and transporting layer, the film thickness and the formation method are same as those described in the above-mentioned first aspect.

(ii) Electron Injecting and Transporting Layer

The electron injecting and transporting layer in this embodiment may be: an electron injecting layer having an electron injecting function of stably injecting the electron injected from the cathode into the light emitting layer; an electron transporting layer having an electron transporting function of transporting the electron injected form the cathode into the light emitting layer; a lamination of the electron injecting layer and the electron transporting layer; or a single layer having both the electron injecting function and the electron transporting function.

The electron injecting and transporting layer contains the material having a liquid repellent functional group. In the case the electron injecting and transporting layer is a lamination of the electron injecting layer and the electron transporting layer, they are laminated in the order of the electron injecting layer and the electron transporting layer. Accordingly, only the electron transporting layer may contain the material having a liquid repellent functional group.

As the electron injecting and transporting layer, there are two preferable aspects. A first aspect of the electron injecting and transporting layer contains an electron injecting and transporting material having electron injecting and transporting properties and a liquid repellent material having a liquid repellent functional group. A second aspect of the electron injecting and transporting layer contains a single material having a portion with electron injecting and transporting properties and a portion having a liquid repellent functional group. Hereafter, each embodiment will be explained.

### (First Aspect)

For the electron injecting and transporting layer of the first aspect, an electron injecting and transporting material having electron injecting and transporting properties and a liquid repellent material having a liquid repellent functional group are used.

The electron injecting and transporting material is not particularly limited as long as it is a material capable of stably transporting the electron injected from the cathode into the light emitting layer and it can be selected optionally depending on the kind of the above-mentioned electron injecting and transporting layer. The electron injecting and transporting material may be: an electron injecting material having electron injecting properties; an electron transporting material having electron transporting properties; or a material having both electron injecting properties and electron transporting properties.

As examples of the electron injecting material, an alkaline metal or an alkaline earth metal alone, such as Ba, Ca, Li, Cs, Mg and Sr; an alloy of an alkaline metal such as aluminum lithium alloy; an oxide of an alkaline metal or an alkaline earth metal such as magnesium oxide and strontium oxide; a fluoride of an alkaline metal or an alkaline earth metal such as magnesium fluoride, calcium fluoride, strontium fluoride; barium fluoride, lithium fluoride and cesium fluoride, or an organic complex of an alkaline metal such as polymethyl methacrylate and sodium polystyrene sulfonate can be presented. Moreover, these can be used in a laminated state such as Ca/Lif.

Among the above-mentioned examples, the fluoride of an alkaline earth metal is preferable. This is because the fluoride of an alkaline earth metal has a high melting point and the heat resistance can be improved.

Moreover, as examples of the electron transporting material, bathocuproine (BCP), phenanthroline derivatives such as bathophenanthroline (Bpehn), triazol derivatives, oxadiazol derivatives, or aluminum quinolinol complexes such as tris(8-quinolinol)aluminum complex (Alq₃) can be presented. In general, when a polymer based material is used for the light emitting layer, the hole blocking properties can be improved by using a low polymer based material for the electron transporting layer.

Furthermore, as the material having both the electron injecting properties and the electron transporting properties, an electron transporting material with an alkaline metal or an alkaline earth metal such as Li, Cs, Ba and Sr doped can be presented. As the electron transporting material, bathocuproine (BCP), or phenanthroline derivatives such as bathophenanthroline (Bpehn) can be presented as examples. Moreover, the mole ratio of the electron transporting material and the metal to be doped is preferably in the range of 1:1 to 1:3, and more preferably in the range of 1:1 to 1:2. An electron transporting material with an alkaline metal or an alkaline earth metal doped has a relatively higher electron mobility so as to provide a high transmittance compare to the case of using a metal alone.

In particular, it is preferable that the electron transporting material has a relatively high resistance. This is because if the resistance is too low, the cross-talk may be generated.

Since the liquid repellent material is same as described in the above-mentioned item of the hole injecting and transporting layer, the explanation thereof is not repeated here.

The liquid repellent material content in the electron injecting and transporting layer is not particularly limited as long as it is an amount capable of providing the liquid repellent properties to the electron injecting and transporting layer without inhibiting the transportation of the electron. Specifically, in the case of using the above-mentioned electron injecting material, the liquid repellent material content in the electron injecting and transporting layer (electron injecting layer) is preferably in the range of 0.1% by weight to 50% by weight, and more preferably in the range of 1% by weight to 20% by weight. In the case of using the above-mentioned electron transporting material, the liquid repellent material content in the electron injecting and transporting layer (electron transporting layer) is preferably in the range of 0.1% by weight to 50% by weight, and more preferably in the range of 1% by weight to 30% by weight. Furthermore, in the case of using the above-mentioned material having both the electron injecting properties and the electron transporting properties, the liquid repellent material content in the electron injecting and transporting layer is preferably in the range of 0.1% by weight to 50% by weight, and it is more preferably in the range of 1% by weight to 20% by weight. If the liquid repellent material content is less than the above-mentioned range, the liquid repellent properties may not be obtained sufficiently. If the liquid repellent material content is more than the range, the electron transportation may be inhibited.

The film thickness of the electron injecting and transporting layer is not particularly limited as long as it is a film thickness capable of sufficiently performing its function and capable of forming the wettability changed pattern. Specifically, when using the above-mentioned electron injecting material, the film thickness of the electron injecting and transporting layer (electron injecting layer) is in the range of 0.1 nm to 200 nm, and more preferably in the range of 0.5 nm to 100 nm. When using the above-mentioned electron transporting material, the film thickness of the electron injecting and transporting layer (electron transporting layer) is in the range of 1 nm to 100 nm, and more preferably in the range of 1 nm to 50 nm. Furthermore, when using the above-mentioned material having both the electron injecting properties and the electron transporting properties, the film thickness of the electron injecting and transporting layer is in the range of 0.1 nm to 100 nm, and more preferably in the range of 1 nm to 50 nm. If the film thickness of the electron injecting and transporting layer is too thin, the wettability difference may not be provided clearly so that the wettability changed pattern formation may be difficult. If the film thickness of the electron injecting and transporting layer is too thick, the electron transportation may be inhibited.

The contact angle with a liquid of the electron injecting and transporting layer and the formation method are same as those of the above-mentioned hole injecting and transporting layer.

### (Second Aspect)

For the electron injecting and transporting layer of the second aspect, a single material having a portion with electron injecting and transporting properties and a portion having a liquid repellent functional group is used.

The portion having the electron injecting and transporting properties is not particularly limited as long as it can stably transport the electron injected from the cathode into the light emitting layer, and to be hardly deteriorated or decomposed by the action of the photocatalyst. The portion having the electron injecting and transporting properties may have: the electron injecting properties, or the electron transporting properties, both the electron injecting properties and the electron transporting properties, and it may be selected optionally according to the kind of the above-mentioned electron injecting and transporting layer.

As the portion having the electron injecting and transporting properties, for example, triazol derivatives, oxadiazol derivatives, or aluminum quinolinol complexes can be presented.

Since the liquid repellent functional group is same as described in the above-mentioned item of the hole injecting and transporting layer, the explanation is omitted.

In particular, it is preferable that the single material having the portion with the electron injecting and transporting properties and the portion with the liquid repellent functional group has a relatively high resistance. This is because the resistance is too low, the cross-talk may be generated.

The film thickness of the electron injecting and transporting layer is same as the above-mentioned first aspect, and the contact angle with a liquid of the electron injecting and transporting layer and the formation method are same as the above-mentioned hole injecting and transporting layer.

### (2) Electrode Layer

The electrode layer in this embodiment may either be an anode or a cathode. In general, the organic EL elements can be produced stably by laminating from the anode side at the time of production. Thus, the electrode layer is preferably an anode.

The material for forming the electrode layer is not particularly limited as long as it is a conductive material.

For example, in the case of providing the organic EL element shown in FIG. 1E of a bottom emission type, or in the case of irradiating the energy from the substrate side in the wettability changed pattern forming step to be described later, it is preferable that the electrode layer is transparent. As example of a conductive and transparent material, In—Zn—O (IZO), In—Sn—O (ITO), ZnO—Al, or Zn—Sn—O can be presented preferably.

Moreover, for example, in the case of providing the organic EL element shown in FIG. 1E of a top emission type, transparency is not required to the electrode layer. In this case, a metal can be used as a conductive material. Specifically, Au, Ta, W, Pt, Ni, Pd, Cr, an Al alloy, a Ni alloy, and a Cr alloy can be presented as examples.

As the method for forming the electrode layer, common electrode forming methods can be used, and a sputtering method, an ion plating method, or a vacuum deposition method, can be presented. Moreover, as the method for patterning the electrode layer, a photolithography method can be presented.

### (3) Substrate

The substrate in this embodiment is for supporting the electrode layer the charge injecting and transporting layer, and other members.

For example, in the case of providing the organic EL element shown in FIG. 1E of a bottom emission type, or in the case of irradiating the energy from the substrate side in the wettability changed pattern forming step to be described later, it is preferable that the substrate is transparent. As a transparent substrate, for example, quartz, or glass can be presented.

Moreover, for example, in the case of providing the organic EL element shown in FIG. 1E of a top emission type, transparency is not required to the substrate. In this case, in addition to the above-mentioned materials, a metal such as aluminum and its alloy, plastic, woven fabrics, or non-woven fabrics can be used for the substrate.

### 2. Wettability Changed Pattern Forming Step

The wettability changed pattern forming step in this embodiment is a step of forming a wettability changed pattern with the wettability changed on the charge injecting and transporting layer surface by the energy irradiation in pattern after disposing a photocatalyst processing layer substrate, in which at least a photocatalyst processing layer containing a photocatalyst is formed on a base member, with a gap capable of providing the effect of the photocatalyst accompanied by the energy irradiation to the charge injecting and transporting layer.

Hereafter, the photocatalyst processing layer substrate, the arrangement of the photocatalyst processing layer substrate and the charge injecting and transporting layer, the energy irradiation, and the wettability changed pattern will be explained.

### (1) Photocatalyst Processing Layer Substrate

In the present invention, at the time of forming the wettability changed pattern on the surface of the charge injecting and transporting layer whose wettability changes by the action of the photocatalyst accompanied by the energy irradiation, a photocatalyst processing layer substrate having a photocatalyst processing layer containing a photocatalyst is used for providing the action of the photocatalyst to the charge injecting and transporting layer. By disposing the photocatalyst processing layer substrate with a predetermined gap to the charge injecting and transporting layer and irradiating the energy in pattern, the wettability changed pattern can be formed on the charge injecting and transporting layer surface.

The photocatalyst processing layer substrate used in the present invention comprises a base member, and a photocatalyst processing layer formed on the base member. Moreover, a light shielding part may be formed in pattern on the photocatalyst processing layer substrate. Hereafter, the photocatalyst processing layer, the base member and the light shielding part will be explained.

(i) Photocatalyst Processing Layer

The photocatalyst processing layer used in the present invention contains a photocatalyst. The photocatalyst processing layer is not particularly limited as long as it has the configuration of changing the wettability of the charge injecting and transporting layer surface by the photocatalyst in the photocatalyst processing layer. For example, the photocatalyst processing layer may be made of a photocatalyst and a binder, or it may be made of a photocatalyst alone. In the case of a photocatalyst processing layer made of a photocatalyst alone, the efficiency with respect to the wettability change of the charge injecting and transporting layer surface can be improved so that it is advantageous in terms of costs such as of the processing time reduction. Moreover, in the case of a photocatalyst processing layer made of a photocatalyst and a binder, it is advantageous in that the photocatalyst processing layer formation can be facilitated.

As the photocatalyst used in the present invention, for example, those known as an optical semiconductor such as titanium dioxide (TiO₂), zinc oxide (ZnO), tin oxide (Sn₂), strontium titanate (SrTiO₃), tungsten oxide (WO₃), bismuth oxide (Bi₂O₃), iron oxide (Fe₂O₃) can be presented. These photocatalyst can be used by one or a mixture.

In the present invention, titanium dioxide is used preferably since it is advantageous due to its high band gap energy, chemical stability, non-hazardous properties, and easy availability. As the titanium dioxide, there are of the anatase type and the rutile type exist and either can be used in the present invention. In particular, it is preferable to use the anatase type titanium dioxide. The anatase type titanium dioxide has the exciting wavelength at 380 nm or less.

As the anatase type titanium dioxide, a hydrochloric acid peptisation type anatase type titania sol (STS-02, an average particle size 7 nm, produced by ISHIHARA SANGYO KAISHA, LTD.; ST-K01 produced by ISHIHARA SANGYO KAISHA, LTD.), and a nitric acid peptisation type anatase type titania sol (produced by NISSAN CHEMICAL INDUSTRIES, LTD., TA-15, average particle size 12 nm) can be presented as examples.

The photocatalyst reaction can be carried out more effectively with a smaller particle size of the photocatalyst, and thus it is preferable. The average particle size is preferably 50 nm or less, and it is particularly preferable to use a photocatalyst of 20 nm or less.

Although the function mechanism of the photocatalyst represented by the titanium dioxide is not always clear, it is considered that the photocatalyst brings about the oxidation-reduction reaction by the energy irradiation to generate an active oxygen species such as a super oxide radical (.O₂⁻) and a hydroxyl radical (.OH) so that the generated active oxygen species influence the chemical structure of an organic material. In the present invention, it is regarded that active oxygen species function to the organic material in the charge injecting and transporting layer disposed in the vicinity of the photocatalyst processing layer.

Moreover, in the case the photocatalyst processing layer is made of a photocatalyst and a binder, the binder to be used preferably has a high bonding energy such that the principal skeleton cannot be decomposed by the photo excitation of the photocatalyst. As such a binder, an organopolysiloxane can be presented as examples.

As the binder, an amorphous silica precursor can be used. This amorphous silica precursor is preferably a silicon compound represented by the general formula SiX₄, where X is a silicon compound such as halogen, a methoxy group, an ethoxy group or an acetyl group; a silanol which is a hydrolyzate thereof; or a polysiloxane having an average molecular weight of 3000 or less. Specific examples include tetraethoxysilane, tetraisopropoxysilane, tetra-n-propoxysilane, tetrabutoxysilane, and tetramethoxysilane. These can be used alone or as a mixture.

When the photocatalyst processing layer is made of the photocatalyst and the binder, the content of the photocatalyst in the photocatalyst processing layer can be set in the range of 5 to 60% by weight, and preferably in the range of 20 to 50% by weight.

The photocatalyst processing layer may contanina a surfactant other than the photocatalyst and the binder. As a surfactant, hydrocarbon based surfactants such as the respective series of NIKKOL, BL, BC, BO, and BB manufactured by Nikko Chemicals Co., Ltd., and fluorine based or silicone based nonionic surfactants such as ZONYL FSN and FSO manufacture by Du Pont Kabushiki Kaisya, Surflon S-141 and 145 manufactured by ASAHI GLASS CO., LTD., Megaface F-141 and 144 manufactured by DAINIPPON INK AND CHEMICALS, Inc., FTERGENT F-200 and F251 manufactured by NEOS, UNIDYNE DS-401 and 402 manufactured by DAIKIN INDUSTRIES, Ltd., and Fluorad FC-170 and 176 manufactured by 3M can be cited. Cationic surfactants, anionic surfactants and amphoteric surfactants can be also used.

Other than the surfactants, the photocatalyst processing layer may contain oligomers and polymers such as polyvinyl alcohol, unsaturated polyester, acrylic resins, polyethylene, diallyl phthalate, ethylene propylene diene monomer, epoxy resins, phenol resins, polyurethane, melamine resins, polycarbonate, polyvinyl chloride, polyamide, polyimide, styrene-butadiene rubber, chloroprene rubber, polypropylene, polybutylene, polystyrene, polyvinyl acetate, polyester, polybutadiene, polybenzimidazole, polyacrylonitrile, epichlorohydrine, polysulfide, and polyisoprene.

The thickness of the photocatalyst processing layer is preferably in the range of 0.05 to 10 μm.

Moreover, the wettability of the surface of the photocatalyst processing layer may either be lyophilic or liquid repellent.

As examples of the method for forming the photocatalyst processing layer made of photocatalyst alone, a sputtering method, a CVD method, and a method of using a vacuum film production method such as a vacuum deposition method can be presented. By forming the photocatalyst processing layer by the vacuum film production method, a photocatalyst processing layer made of photocatalyst alone can be provided as an even film. Thereby, the wettability of the charge injecting and transporting layer surface can be changed evenly. Moreover, since the photocatalyst processing layer is made of a photocatalyst alone, the wettability of the charge injecting and transporting layer surface can be changed efficiently compared with the case of using a binder.

As examples of the method for forming a photocatalyst processing layer made of photocatalyst alone, when the photocatalyst is titanium dioxide, a method of forming an amorphous titania on the base member, and then having the phase change by baking to the crystalline titania can be presented.

The amorphous titania used here can be obtained for example, by the hydrolysis and dehydration condensation of an inorganic salt of a titanium such as titanium tetrachloride and titanium sulfate, or by hydrolysis and dehydration condensation of an organic titanium compound such as tetraethoxy titanium, tetraisopropoxy titanium, tetra-n-propoxy titanium, tetrabutoxy titanium and tetramethoxy titanium in the presence of an acid. Then, it can be modified into an anatase type titanium by baking at 400° C. to 500° C., and into a rutile type titanium by baking at 600° C. to 700° C.

As to the method for forming the photocatalyst processing layer made of the photocatalyst and the binder, in the case of using an organopolysiloxane as the binder, a method of preparing a photocatalyst processing layer forming coating solution by dispersing the photocatalyst and the organopolysiloxane as the binder in a solvent as needed with other additives, and applying the photocatalyst processing layer forming coating solution onto a base member can be used. Moreover, in the case a ultraviolet ray curable component is contained as the binder, the curing process maybe carried out by exposing ultraviolet ray after the application.

As the solvent used at the time, an alcohol based organic solvent such as ethanol and isopropanol can be used preferably. As the applying method, a common method such as a spin coating method, a spray coating method, a dip coating method, a roll coating method and a bead coating method can be used.

Moreover, as to the method for forming the photocatalyst processing layer made of the photocatalyst and the binder, in the case of using an amorphous silica precursor as the binder, a method of preparing a photocatalyst processing layer forming coating solution by evenly dispersing the particles of the photocatalyst and the amorphous silica precursor in a non-water based solvent, applying the solution onto a base member, and forming a silanol by the hydrolysis of the amorphous silica precursor with the moisture content in the air for the dehydration polycondensation at room temperature can be used. By carrying out the dehydration polycondensation of the silanol at 100° or higher, the silanol polymerization degree can be increased so that the strength of the film surface can be improved.

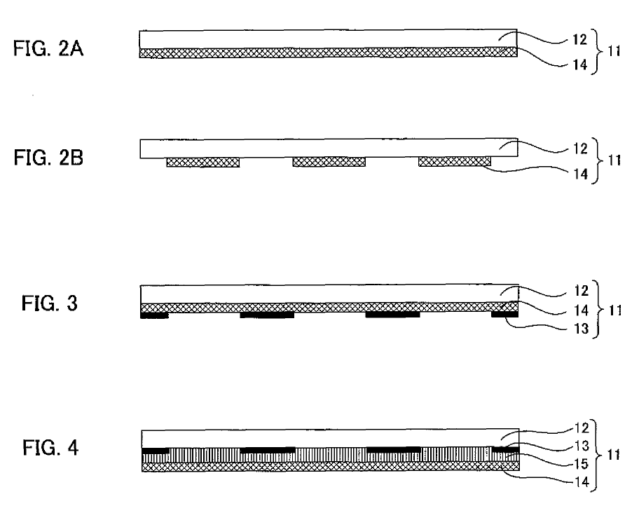

As to the position for forming the photocatalyst processing layer, for example as shown in FIG. 2A, a photocatalyst processing layer 14 may be formed on the entire surface of a base member 12, or as shown in FIG. 2B, the photocatalyst processing layer 14 may be formed in pattern on the base member 12.

In the case the photocatalyst processing layer is formed in pattern, the wettability of the charge injecting and transporting layer surface can be changed by the entire surface irradiation without the need of the pattern irradiation using such as a photo mask at the time of the energy irradiation with the photocatalyst processing layer disposed with a predetermined gap to the charge injecting and transporting layer. Moreover, since the wettability is changed only in the charge injecting and transporting layer surface actually facing the photocatalyst processing layer, the energy irradiation direction may be any direction as long as the energy is irradiated to the portion where the photocatalyst processing layer and the charge injecting and transporting layer face each other. Furthermore, the energy to be irradiated is not limited to parallel one such as a parallel beam.

The method for patterning the photocatalyst processing layer is not particularly limited and a photolithography method can be presented as an example.

(ii) Base Member

The transparency of the base member used for the photocatalyst processing layer substrate can be selected optionally depending on the energy irradiation direction to be described later and the direction of taking out the light beam of the organic EL element to be obtained.

For example, when the organic EL element shown in FIG. 1E is of a top emission type and the substrate or the electrode layer in the organic EL element is opaque, the energy irradiation direction should be inevitably from the photocatalyst processing layer substrate side. Moreover, as shown in FIG. 1B, when the light shielding part 13 is formed in pattern on the photocatalyst processing layer substrate 11, and the energy irradiation is carried out in pattern using the light shielding part 13, the energy irradiation should be also carried out from the photocatalyst processing layer substrate side. Therefore, in these cases, the base member should be transparent.

On the other hand, when the organic EL element shown in FIG. 1E is of a bottom emission type, the energy irradiation can be carried out from the substrate side in the organic EL element. Therefore, in this case, the base member needs not be transparent.

Moreover, the base member may be flexible one, such as a resin film, or one without flexibility such as a glass substrate.

Although the base member is not particularly limited, since the photocatalyst processing layer substrate is to be used repeatedly, one having a predetermined strength, with its surface provided with preferable adhesion properties to the photocatalyst processing layer can be used preferably. Specifically, as the material comprising the base member, glasses, ceramics, metals, and plastics can be presented as examples.

Moreover, for improving the adhesion properties between the base member surface and the photocatalyst processing layer, an anchor layer may be formed on the base member. As examples of the material for forming the anchor layer, a silane based or a titanium based coupling agent can be presented.

(iii) Light Shielding Part

Light shielding parts may be formed in pattern on the photocatalyst processing layer substrate used in the present invention. When using a photocatalyst processing layer substrate having the light shielding parts in pattern, use of a photo mask or drawing irradiation with a laser beam is not required for the energy irradiation. Therefore, in this case, since positioning of the photocatalyst processing layer substrate and the photo mask is not needed, a simple step can be realized. Moreover, since expensive equipment for the drawing irradiation is not also required, it is advantageous in terms of the cost.

As to the position for forming the light shielding part, for example as shown in FIG. 1B, the light shielding parts 13 may be formed in pattern on the base member 12, with the photocatalyst processing layer 14 formed on the light shielding parts 13. Moreover, as shown in FIG. 3, the photocatalyst processing layer 14 may be formed on the base member 12, with the light shielding parts 13 formed in pattern on the photocatalyst processing layer 14. Furthermore, it is not shown in a figure, but the light shielding parts may be formed in pattern on the surface of the side of the base member where no photocatalyst processing layer formed.

In the case the light shielding part is formed on the base member, and in the case the light shielding part is formed on the photocatalyst processing layer, the light shielding part is disposed in the vicinity of the portion where the photocatalyst processing layer and the charge injecting and transporting layer are disposed with a gap compared to the case of using a photo mask. Accordingly, influence of energy scattering in the base member, or the like can be reduced. Therefore, the energy pattern irradiation can be carried out extremely precisely.

Furthermore, in the case the light shielding part is formed on the photocatalyst processing layer, by providing the film thickness of the light shielding part equally to the distance of the gap at the time of disposing the photocatalyst processing layer and the charge injecting and transporting layer with a predetermined gap, the light shielding part can be used as a spacer for constantly providing the gap. That is, by disposing the light shielding part and the charge injecting and transporting layer in a closely contacted state at the time of disposing the photocatalyst processing layer and the charge injecting and transporting layer with a predetermined gap, a predetermined gap can be maintained. Then, by irradiating the energy from the photocatalyst processing layer substrate in this state, the wettability changed pattern can be formed precisely on the charge injecting and transporting layer surface.

Moreover, in the case the light shielding part is formed on the side of the base member where no photocatalyst processing layer formed, since the photo mask can be closely contacted on the light shielding part surface to the detachable degree, it is preferable in the case of changing the production of the organic EL element by a small lot.

The method for forming the light shielding part is not particularly limited, and may be appropriately selected in accordance with properties of the face where the light shielding part is to be formed, power for shielding the energy required, and others.

For instance, a metal thin film that is made of such as chromium and formed into a thickness of about 1000 to 2000 Å by sputtering method, a vacuum deposition method or other method is formed and patterned to form a shielding part. As the patterning method, common patterning methods can be used.

A method may be one by which a layer that contains light-shielding particles such as carbon particulates, metal oxides, inorganic pigments and organic pigments in a resin binder is patterned. As the resin binders, polyimide resins, acrylic resins, epoxy resins, polyacrylamide, polyvinyl alcohol, gelatin, casein, cellulose and the like can be used singularly or in combination of two or more kinds. Furthermore, a photosensitive resin and an O/W emulsion type resin composition such as emulsified reactive silicone can be used. As a method of patterning, common methods such as a photolithography method and a printing method can be used.

A thickness of such light shielding part using the resin binder can be set in the range of 0.5 to 10 μm.

(iv) Primer Layer

In the present invention, as mentioned above, in the case the light shielding parts are formed in pattern on the base member and the photocatalyst processing layer is formed on the light shielding parts, for example as shown in FIG. 4, it is preferable that the primer layer 15 is formed between the light shielding part 13 and the photocatalyst processing layer 14.

The effect and function of this primer layer are not necessarily clear, but would be as follows: the primer layer exhibits a function of preventing the diffusion of impurities from openings which are present in the light shielding part and between the light shielding parts, the impurities being factors for blocking the wettability change of the charge injecting and transporting layer by action of the photocatalyst, in particular, residues generated when the light shielding parts are patterned, or metal, metal ion impurities, or the like. Accordingly, the formation of the primer layer between the light shielding part and the photocatalyst processing layer makes it possible to progress the wettability change process with high sensitivity so that a high resolution wettablity changed pattern can be obtained.

The primer layer inhibits the impurities present not only in the light shielding part but also in the openings formed between the light shielding parts from adversely affecting on an action of the photocatalyst; accordingly, the primer layer is preferably formed over an entire surface of the patterned light shielding parts formed and the openings. The primer layer is arranged such that the photocatalyst processing layer and the light shielding part are not in physical contact.

A material that forms the primer layer, though not particularly restricted, is preferably an inorganic material that is not likely to be decomposed by action of the photocatalyst. Specifically, amorphous silica can be cited for the inorganic material. A precursor of the amorphous silica is preferably a silicon compound that is represented by a general formula, SiX₄, where X being a silicon compound such as halogen, a methoxy group, an ethoxy group, or an acetyl group, silanol that is a hydrolysate thereof, or polysiloxane having an average molecular weight of 3000 or less.

A film thickness of the primer layer is preferably in the range of 0.001 to 1 μm and particularly preferably in the range of 0.001 to 0.5 μm.

### (2) Arrangement of the Photocatalyst Processing Layer Substrate and the Charge Injecting and Transporting Layer

In this embodiment, the photocatalyst processing layer substrate is disposed with a gap capable of providing the action of the photocatalyst accompanied by the energy irradiation to the charge injecting and transporting layer. In general, the photocatalyst processing layer of the photocatalyst processing layer substrate and the charge injecting and transporting layer are disposed with a gap capable of providing the action of the photocatalyst accompanied by the energy irradiation to the charge injecting and transporting layer.

The gap includes also a state where the photocatalyst processing layer and the charge injecting and transporting layer contact.

Specifically, the gap between the photocatalyst processing layer and the charge injecting and transporting layer is preferably 200 μm or less. Since the photocatalyst processing layer and the charge injecting and transporting layer are disposed with a predetermined gap, the active oxygen species generated by the function of the oxygen, the water and the photocatalyst can easily be attached or detached. If the gap between the photocatalyst processing layer and the charge injecting and transporting layer is wider than the above-mentioned range, the active oxygen species generated by the photocatalyst function can hardly reach the charge injecting and transporting layer so that the wettability change speed may be slowed. If the gap between the photocatalyst processing layer and the charge injecting and transporting layer is too narrow, the active oxygen species generated by the function of the oxygen, the water and the photocatalyst can hardly be attached or detached so that the wettability change speed may be slowed.

In consideration to the extremely preferable pattern accuracy, the high sensitivity of the photocatalyst, and the preferable wettability change efficiency, the gap is more preferably in the range of 0.2 μm to 20 μm, and further preferably in the range of 1 μm to 10 μm.

On the other hand, in the case of producing a large area organic EL element of for example 300 mm×300 mm, it is extremely difficult to provide the minute gap as mentioned above between the photocatalyst processing layer substrate and the charge injecting and transporting layer. Therefore, when producing an organic EL element of a relatively large area, the gap is preferably in the range of 5 μm to 100 μm, and further preferably in the range of 10 μm to 75 μm. Since the gap is in the above-mentioned range, deterioration of the pattern accuracy such as blurring of the pattern can be restrained, and, deterioration of the wettability change efficiency due to deterioration of the photocatalyst sensitivity can be restrained.

Moreover, at the time of the energy irradiation to the relatively large area as mentioned above, it is preferable to set the gap in the positioning device of the energy irradiating device for the photocatalyst processing layer substrate and the charge injecting and transporting layer in the range of 10 μm to 200 μm, in particular, in the range of 25 μm to 75 μm. Since the setting value of the gap is in the above-mentioned range, the photocatalyst processing layer substrate and the charge injecting and transporting layer can be arranged without contacting each other and without drastic deterioration of the pattern accuracy or drastic deterioration of the photocatalyst sensitivity.

In the present invention, such an arrangement state with a gap may be maintained at least during the energy irradiation.

As the method for arranging the photocatalyst processing layer and the charge injecting and transporting layer with such an extremely narrow gap provided evenly, a method of using a spacer can be presented as an example. According to this method of using a spacer, even gap can be provided and the action of the photocatalyst is not provided to the charge injecting and transporting layer surface in the portion to be contacted by the spacer. Accordingly, by providing the spacer with the same pattern as the above-mentioned wettability changed pattern, a predetermined wettability changed pattern can be formed on the charge injecting and transporting layer surface.

In the present invention, although the spacer may be formed as a member, it is preferable that the spacer is formed on the photocatalyst processing layer of the substrate to simplify the process. In this case, the advantages as mentioned in the above-mentioned item of the light shielding part can be provided.

The spacer may have a function of protecting the charge injecting and transporting layer surface so as not to apply the action of the photocatalyst to the charge injecting and transporting layer surface. Therefore, the spacer may not have shielding properties with respect to the energy to be irradiated.

### (3) Energy Irradiation

In this embodiment, a wettability changed pattern is formed on the charge injecting and transporting layer surface by the pattern irradiation of the energy from a predetermined direction after disposing the photocatalyst processing layer and the charge injecting and transporting layer with a predetermined gap.

The wavelength of a light beam used for the energy irradiation is set in general in the range of 450 nm or less, and set more preferably in the range of 380 nm or less. This is because the photocatalyst used preferably for the photocatalyst processing layer is titanium dioxide as mentioned above, and a light beam of the above-mentioned wavelength is preferable as the energy for activating the photocatalyst function by the titanium dioxide.

As a light source to be used for the energy irradiation, a mercury lamp, a metal halide lamp, a xenon lamp, an excimer lamp, and other various light sources can be presented.

Moreover, as the method for the energy irradiation in pattern, in addition to a method for carrying out the pattern irradiation via a photo mask using these light sources, a method of a pattern drawing irradiation using a laser beam such as the excimer and the YAG can also be used.

The energy irradiation amount at the time of the irradiation is an amount necessary for changing the wettability of the charge injecting and transporting layer surface by the action of the photocatalyst in the photocatalyst processing layer.

At the time, it is preferable to carry out the energy irradiation while heating the photocatalyst processing layer because the sensitivity can be raised so as to efficiently change the wettability. Specifically, it is preferable to heat in the range of 30° C. to 80° C.

The energy irradiation direction can be determined depending on whether or not the light shielding part is formed on the photocatalyst processing layer substrate, the light taking out direction of the organic EL element, or other factors.

For example, if the light shielding part is formed on the photocatalyst processing layer substrate and the base member of the photocatalyst processing layer substrate is transparent, the energy irradiation is carried out from the photocatalyst processing layer substrate side. In this case, when the light shielding part is formed on the photocatalyst processing layer and the light shielding part functions as a spacer, the energy may be irradiated from the side of the photocatalyst processing layer substrate or the substrate side.

Further, if the photocatalyst processing layers are formed in pattern, as mentioned above, the energy irradiation direction may be of any direction as long as the energy is irradiated to the portion with the photocatalyst processing layer and the charge injecting and transporting layer face each other.

Similarly, in the case of using the above-mentioned spacer, as long as the energy is irradiated to the portion with the photocatalyst processing layer and the charge injecting and transporting layer face each other, the energy irradiation direction may be of any direction.

Furthermore, in the case of using a photo mask, the energy is irradiated from the side with the photo mask disposed. In this case, the side with the photo mask disposed should be transparent.

After the energy irradiation, the photocatalyst processing layer substrate is detached from the charge injecting and transporting layer.

### (4) Wettability Changed Pattern

The wettability changed pattern in this embodiment is to be formed on the charge injecting and transporting layer surface and comprises a lyophilic region as the energy irradiated portion and a liquid repellent region as the energy unirradiated portion.

In the present invention, the lyophilic region is the energy irradiated portion, which has been changed to of lower the contact angle with respect to a liquid by the energy irradiation. The liquid repellent region is the energy unirradiated portion, which has a contact angle with respect to a liquid larger than that of the lyophilic region.

In the lyophilic region as the energy irradiated portion, it is preferable that the contact angle with respect to a liquid having the same surface tension as that of the organic EL layer forming coating solution to be applied is 20° or less, more preferably, 15° or less, and particularly preferably 10° or less. In the case the contact angle with respect to a liquid is too high in the lyophilic region, the organic EL layer forming coating solution may hardly be spread so as to cause such as lacking of the organic EL layer.

The method for measuring the contact angle with respect to a liquid is same as mentioned in the above-mentioned item of the charge injecting and transporting layer.

### 3. Organic EL Layer Forming Step

The organic EL layer forming step in this embodiment is a step of forming an organic EL layer containing at least a light emitting layer on the wettability changed pattern.

The organic EL layer used in the present invention comprises one layer containing at least a light emitting layer or a plurality of organic layers. That is, the organic EL layer is a layer including at least a light emitting layer, with the layer configuration of one organic layer or more. In general, in the case of forming an organic EL layer by a wet coating process, since a large number of layers can hardly be laminated because of a the solvent, it is formed with one or two organic layers in most cases. However, a larger number of layers can be realized by skillfully preparing the organic material for having a different solubility to the solvent, or using the vacuum deposition method in combination.

As the organic layer comprising the organic EL layer other than the light emitting layer, a hole injecting layer, a hole transporting layer, an electron injecting layer and an electron transporting layer can be presented. As the organic layer, a layer for improving the re-bonding efficiency by preventing piercing of the hole or the electron such as a carrier block layer, and a layer further preventing diffusion of the exciton for enclosing the exciton in the light emitting layer can be presented as examples.

In this embodiment, since the organic EL layer is formed on the charge injecting and transporting layer, it is preferable to form the light emitting layer as the organic EL layer. That is, it is preferable to form the light emitting layers in pattern, utilizing the wettability changed pattern formed on the charge injecting and transporting layer surface.

Moreover, in this embodiment, an intermediate layer may be formed between the charge injecting and transporting layer and the light emitting layer for evenly forming the light emitting layer on the charge injecting and transporting layer. In this case, the intermediate layers are formed in pattern only on the lyophilic regions, utilizing the wettability changed pattern formed on the charge injecting and transporting layer. Since the intermediate layer surface is lyophilic and the regions without formation of the intermediate layers are liquid repellent regions, the light emitting layers can also be formed in pattern according to the wettability difference.

The method for forming the organic EL layer is not particularly limited as long as it is a method capable of forming the organic EL layers in pattern, utilizing the wettability difference of the lyophilic region and the liquid repellent region comprising the wettability changed pattern. For example, the organic EL layer can be formed only on the lyophilic region by applying the organic EL layer forming coating solution on the wettability changed pattern.

As examples of the method for applying the organic EL layer forming coating solution, a method for applying onto the entire surface such as a spin coating method, a casting method, a dipping method, a bar coating method, a blade coating method, a gravure coating method, a spray coating method and a printing method, and an ejection method using a dispenser or an ink jet can be presented. Among them, the ejection method is preferable, and in particular, the ink jet method is preferable. According to the method, a highly precise pattern can be formed, utilizing the wettability changed pattern.

Hereafter, the light emitting layer as the configuration essential to the organic EL layer will be explained.

### (1) Light Emitting Layer

In this embodiment, the light emitting layer can be formed only on the lyophilic region by applying the light emitting layer forming coating solution on the wettability changed pattern formed on the charge injecting and transporting layer surface. The light emitting layer forming coating solution can be prepared by dispersing or dissolving a light emitting material in a solvent. In the case of forming the light emitting layers of the three principal colors of red, green and blue, the light emitting layer forming coating solutions of respective colors are used.

The Light emitting material is not particularly limited as long as it contains a material for emitting fluorescence so as to emit a light beam. The light emitting material may have the hole transporting properties or the electron transporting properties. As the light emitting material, a pigment based material, a metal complex based material, and a polymer based material can be presented.

As the pigment based material, cyclopendamine derivatives, tetraphenyl butadiene derivatives, triphenyl amine derivatives, oxadiazol derivatives, pyrazoloquinoline derivatives, distyryl benzene derivatives, distyryl arylene derivativse, silol derivatives, thiophene ring compounds, pyridine ring compounds, perynone derivatives, perylene derivatives, oligothiophene derivatives, triphmanyl amine derivatives, an oxadiazol dimmer, or a pyrazoline dimmer can be presented as examples.

As the metal complex based material, aluminum quinolinol complexes, benzoquinolinol beryrium complexes, benzoxazol zinc complexes, benzothiazol zinc complexes, azomethyl zinc complexses, porphyline zinc complexes, europium complexes, or metal complexes having as the central metal Al, Zn, or Be, or a rare earth metal such as Tb, Eu and Dy, and as the ligand an oxadiazol, thiadiazol, phenyl pyridine, phenyl benzoimidazol, or quinoline structure can be presented.

As the polymer based material, polyparaphenylene vinylene derivatives, polythiophene derivatives, polyparaphenylene derivatives, polysilane derivatives, or polyacetylene derivatives, polyfluorene derivatives, polyvinyl carbazol derivatives, a polymer of the above-mentioned pigment, or metal complex based light emitting materials can be presented.

In the present invention, from the viewpoint of utilizing the advantage of precisely forming the light emitting layer, which is achieved by utilizing the wettability difference of the wettability changed pattern, it is preferable to use the above-mentioned polymer based material as the light emitting material.

Moreover, for the purpose of improving the light emitting efficiency, changing of the light emitting wavelength or the like, a dopant may be added to the light emitting material. As the dopant, for example, perylene derivatives, coumarine derivatives, rubrene derivatives, quinacrydone derivatives, squarium derivatives, porphylene derivatives, styryl based pigments, tetracene derivatives, pyrazoline derivatives, decacyclene, or phenoxazone can be presented.

Moreover, the solvent used for the light emitting layer forming coating solution is not particularly limited as long as it can dissolve or disperse the above-mentioned light emitting material so as to obtain predetermined viscosity and solid component concentration. As the solvent, for example, chloroform, methylene chloride, dichloroethane, tetrahydrofuran, toluene, xylene, tetralin, or tetramethyl benzene can be presented.

In addition to the above-mentioned light emitting material and solvent, various additives may be added to the light emitting layer forming coating solution. For example, in the case of forming the light emitting layer by the ink jet method, a surfactant, or the like may be added to improve the ejection properties.

### (2) Intermediate Layer

In this embodiment, for formation of an even light emitting layer on the charge injecting and transporting layer, an intermediate layer may be formed on the charge injecting and transporting layer before the formation of the light emitting layer.

The material for forming the intermediate layer is not particularly limited as long as it can preferably maintain the film forming properties of the light emitting layer without deteriorating the optical characteristics of the light emitting layer.

The material for forming the intermediate layer may have the hole transporting properties or the electron transporting properties. When the intermediate layer has the hole transporting properties or the electron transporting properties, the hole or the charge can be transported smoothly from the charge injecting and transporting layer to the light emitting layer so that the light emitting efficiency can be improved. In this case, since lamination is carried out in general from the anode side at the time of producing the organic EL element, it is preferable that the electrode layer is an anode, the charge injecting and transporting layer is the hole injecting and transporting layer, and the intermediate layer has the hole transporting function.

The material having the hole transporting properties used for the intermediate layer is not particularly limited as long as it is a material capable of transporting the hole from the charge injecting and transporting layer to the light emitting layer, and it is preferably a material having a high hole mobility. Furthermore, it is preferably a material capable of preventing piercing of the electron moved form the cathode. Thereby, the re-bonding efficiency of the hole and the electron can be improved in the light emitting layer.

As examples of such material having the hole transporting properties, aryl amines, carbazols, fluorene and its derivative can be presented. As the aryl amines, specifically, bis(N-(1-naphthyl-N-phenyl)-bendidine (α-NPD), N,N′-bis-(3-methyl phenyl)-N,N′-bis-(phenyl)-bendidine (TPD), or copoly[3,3′-hydroxy-tetraphenyl bendidine/diethylene glycol]carbonate (PC-TPD-DEG) can be presented as examples. As the specific examples of the carbazols, polyvinyl carbazol (PVCz) can be presented. As the specific examples of the fluorene derivative, poly[(9,9-dioctyl fluorenyl-2,7-diyl)-co-(4,4′-(N-(4-sec-butyl phenyl))diphenyl amine)] (TFB) can be presented. These may be used alone or as a combination.

Moreover, the material having the electron transporting properties used for the intermediate layer is not particularly limited as long as it is a material capable of transporting the electron from the charge injecting and transporting layer to the light emitting layer, and it is preferably a material having a high electron mobility. Furthermore, it is preferably a material capable of preventing piercing of the electron moved from the anode. Thereby, the re-bonding efficiency of the hole and the electron can be improved in the light emitting layer.

As such a material having the electron transporting properties, for example, oxadiazols, triazols, phenanthrolines, or aluminum quinolinol complexes can be presented. As the specific examples of the phenanthrolines, bathocuproine, or bathophenanthroline can be presented, and as the specific examples of the aluminum quinolinol complexes, tris(8-quinolinol)aluminum complex (Alq₃) can be presented. These may be used alone or as a combination.

Moreover, the material for forming the intermediate layer may have the insulation properties. As examples of the material having the insulation properties used for the intermediate layer, a resin such as polycarbonate, polystyrene, polyethylene and polyacrylate can be presented. These may be used alone or as a combination.

Furthermore, the material for forming the intermediate layer may be a mixture of the material having the hole transporting properties or the electron transporting properties and the material having the insulation properties.

The film thickness of the intermediate layer is preferably in the range of 5 nm to 500 nm. If the film thickness of the intermediate layer is less than the above-mentioned range, an even film may not be obtained. If the film thickness of the intermediate layer is more than the range, the driving voltage may be made higher due to too a large the volume resistance of the intermediate layer. When the intermediate layer has the insulation properties without having the hole transporting properties or the electron transporting properties, the film thickness is preferably in the range of 5 nm to 15 nm, and it is particularly preferably in the range of 5 nm to 10 nm.

The intermediate layer can be formed by applying onto the wettability changed pattern formed on the charge injecting and transporting layer surface the intermediate layer forming coating solution prepared by dissolving or dispersing the above-mentioned material in a solvent.

The solvent used for the intermediate layer forming coating solution is not particularly limited as long as it can dissolve or disperse the above-mentioned material so that it can be selected optionally according to the kind of the material. Specifically, chloroform, methylene chloride, dichloroethane, tetrahydrofuran, toluene, or xylene can be presented as examples.

Moreover, the method for applying the intermediate layer forming coating solution is preferably a method capable of evenly forming the intermediate layer. For example, a dip coating method, a roll coating method, a blade coating method, a spin coating method, a micro gravure coating method, a gravure coating method, a bar coating method, a wire bar coating method, a casting method, a ink jet method, a LB method, a flexo printing method, an offset printing method, or a screen printing method can be presented.

### 4. Insulation Layer Forming Step

In this embodiment, an insulation layer forming step for forming an insulation layer between the patterns of the electrode layer on the substrate, with the electrode layers formed in pattern, may be carried out before the above-mentioned charge injecting and transporting layer forming step.

The insulation layer is provided for preventing conduction between the patterns of the electrode layer or conduction between the electrode layer and the counter electrode layer. The portion with the insulation layer formed provides a non light emitting region. The insulation layer is formed between the patterns of the electrode layer on the substrate, and in general, it is formed to cover the end part of the electrode layer pattern.

The material for forming the insulation layer is not particularly limited as long as it has the insulation properties. In particular, it is preferable that the material for forming the insulation layer reflects or absorbs the energy line to be irradiated in the wettability changed pattern forming step. In this case, pattern irradiation can be enabled by the entire surface irradiation of the energy from the substrate side in the wettability changed pattern forming step. Therefore, use of a photo mask or the drawing irradiation with a laser beam is not required at the time of the energy irradiation. As such a material for forming the insulation layer, for example, photo setting type resins such as photosensitive polyimide resins and acrylic based resins, thermosetting type resins, or inorganic materials can be used.

Moreover, as the method for forming the insulation layer, a common method such as a photolithography method and a printing method can be used.

### 5. Counter Electrode Layer Forming Step

In this embodiment, a counter electrode layer forming step for forming a counter electrode layer on the organic EL layer is generally carried out after the above-mentioned organic EL layer forming step.

The counter electrode layer is an electrode having the charge opposite to that of the electrode layer, which may either be an anode or a cathode. In general, at the time of producing an organic EL element, it is preferable that the counter electrode layer is a cathode because the organic EL layer can be produced stably by the lamination from the anode side.

The material for forming the counter electrode layer is not particularly limited as long as it is a conductive material. For example, in the case of providing the organic EL element shown in FIG. 1E of the top emission type, it is preferable that the counter electrode layer is transparent. In the case of providing the organic EL element shown in FIG. 1E of the bottom emission type, the transparency is not required for the counter electrode layer.

Since the material for forming the counter electrode layer and the method for forming the counter electrode layer are same as the electrode layer described in the above-mentioned item of the charge injecting and transporting layer forming step, the explanation is omitted.

### 6. Other Steps

In this embodiment, a step of forming a barrier layer for protecting the organic EL layer such as the light emitting layer from the influence of the oxygen and the water vapor, or a step of forming a low refractive index layer for improving the light taking out efficiency on the counter electrode layer may be carried out.

### II. Second Embodiment

The second embodiment of a manufacturing method of an organic EL element of the present invention comprises: a charge injecting and transporting layer forming step of forming a charge injecting and transporting layer on a substrate with an electrode layer formed; a liquid repellent process step of processing the charge injecting and transporting layer surface to be liquid repellent; a wettability changed pattern forming step of forming a wettability changed pattern with wettability of the charge injecting and transporting layer surface changed by the energy irradiation in pattern after disposing the photocatalyst processing layer substrate, in which a photocatalyst processing layer containing at least a photocatalyst formed on a base member, with a gap capable of providing the action of the photocatalyst accompanied by the energy irradiation to the charge injecting and transporting layer with the liquid repellent process applied; and an organic EL layer forming step of forming an organic EL layer, which includes at least a light emitting layer, on the wettability changed pattern.

The manufacturing method of an organic EL element of this embodiment can be classified into two embodiments according to the liquid repellent process step. Hereafter, each aspect will be explained.

### 1. First Aspect

The first aspect of the manufacturing method of an organic EL element of the present invention comprises: a charge injecting and transporting layer forming step of forming a charge injecting and transporting layer on a substrate with an electrode layer formed; a liquid repellent process step of processing the charge injecting and transporting layer surface to be liquid repellent by inducing plasma using a fluorine compound as introduction gas to the charge injecting and transporting layer; a wettability changed pattern forming step of forming a wettability changed pattern with wettability changed on the charge injecting and transporting layer surface by energy irradiation in pattern after disposing a photocatalyst processing layer substrate, in which a photocatalyst processing layer containing at least a photocatalyst is formed on a base member, with a gap capable of providing the action of the photocatalyst accompanied by the energy irradiation to the charge injecting and transporting layer with the liquid repellent process applied; and an organic EL layer forming step of forming an organic EL layer, which includes at least a light emitting layer, on the wettability changed pattern.

The manufacturing method of an organic EL element of this embodiment will be explained with reference to the drawings.

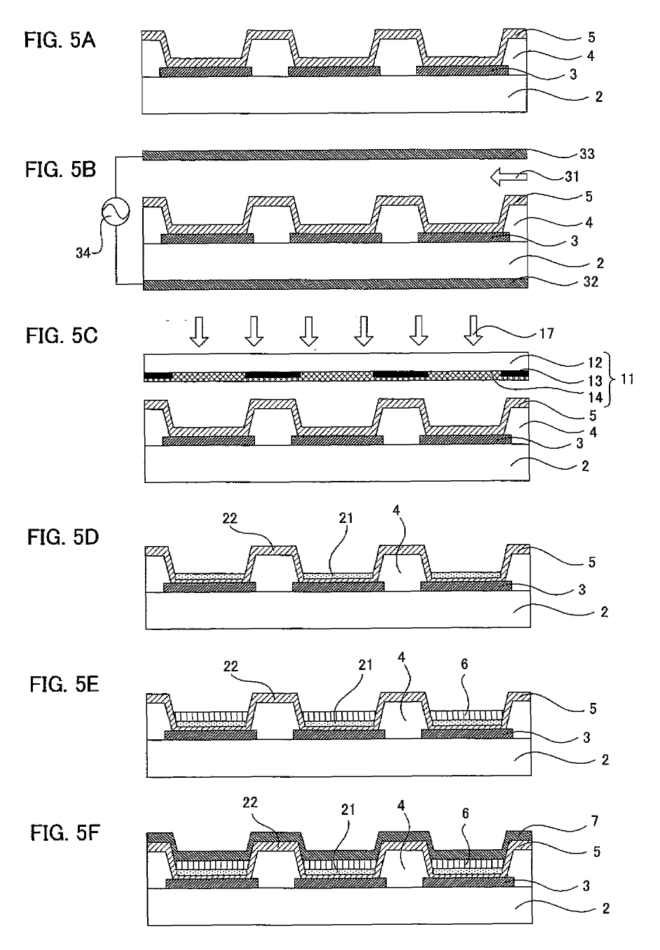

FIGS. 5A to 5F is a process drawing showing an example of the manufacturing method of an organic EL element of this embodiment. First, an electrode layers 3 are formed in pattern on a substrate 2, an insulation layer 4 is formed between the patterns of the electrode layers 3, and a charge injecting and transporting layer 5 is formed on the electrode layer 3 and the insulation layer 4 (FIG. 5A, charge injecting and transporting layer forming step).

The substrate 2 having the electrode layer 3, the insulation layer 4 and the charge injecting and transporting layer 5 formed is disposed in a reaction chamber, and a fluorine compound 31 is supplied into the reaction chamber as the introduction gas, an electric field is applied from a power source 34 with one of the electrodes 32 connected to the substrate 2 and the other electrode 33 facing to the substrate 2 (FIG. 5B, liquid repellent process step). Plasma is induced with the fluorine compound used as the introduction gas to the charge injecting and transporting layer. Thereby, the fluorine is introduced to the organic material in the charge injecting and transporting layer so that the surface of the charge injecting and transporting layer is processed to be liquid repellent.

Next, as shown in FIG. 5C, a photocatalyst processing layer substrate 11 having a base member 12, light shielding part 13 formed in pattern on the base member 12, and a photocatalyst processing layer 14 formed on the base member 12 to cover the light shielding parts 13 is prepared. The photocatalyst processing layer 14 of the photocatalyst processing layer substrate 11 and the charge injecting and transporting layer 5 are disposed to face each other, ultraviolet ray 17 is irradiated. By the ultraviolet ray 17 irradiation, as shown in FIG. 5D, the fluorine introduced into the organic material in the charge injecting and transporting layer 5 is removed so as to change the wettability to lower its contact angle with respect to a liquid in the ultraviolet ray irradiated portion of the charge injecting and transporting layer 5 by the action of the photocatalyst contained in the photocatalyst processing layer 14. Thereby, the ultraviolet ray irradiated portion provides a lyophilic region 21, and the ultraviolet ray unirradiated portion provides a liquid repellent region 22. Then, the photocatalyst processing layer substrate 11 is detached from the charge injecting and transporting layer 5. Thereby, a wettability changed pattern having the lyophilic region 21 and the liquid repellent region 22 is formed on the charge injecting and transporting layer 5 surface. FIGS. 5C and 5D show the wettability changed pattern forming step.

Next, utilizing the wettability difference, an organic EL layer 6 is formed on the lyophilic region 21 by applying the organic EL layer forming coating solution on the wettability changed pattern having the lyophilic region 21 and the liquid repellent region 22 (FIG. 5E, organic EL layer forming step).

Then, a counter electrode layer 7 is formed on the organic EL layer 6 (FIG. 5F). At the time, if the counter electrode layer 7 is provided as a transparent electrode, an organic EL element of the top emission type can be obtained, and if the electrode layer 3 is provided as a transparent electrode, an organic EL element of the bottom emission type can be obtained.

When plasma is induced with a fluorine compound used as the introduction gas, fluorine can be introduced into an organic material so that the surface of the layer containing the organic material can be processed to be liquid repellent. In this aspect, by carrying out the plasma induction in the liquid repellent process step, the surface of the charge injecting and transporting layer can be processed to be liquid repellent. Furthermore, by the energy irradiation to the charge injecting and transporting layer via the photocatalyst processing layer containing the photocatalyst, the fluorine introduced into the organic material in the charge injecting and transporting layer can be removed. Thereby, the energy irradiated portion can be provided as a lyophilic region and the energy unirradiated portion as a liquid repellent region so that a wettability changed pattern by the wettability difference can be formed on the charge injecting and transporting layer surface. Then, the organic EL layer can be patterned, utilizing the wettability changed pattern with the wettability difference formed on the charge injecting and transporting layer surface.

Accordingly, in this embodiment, by removing in the wettability changed pattern forming step the fluorine introduced into the charge injecting and transporting layer during the liquid repellent process step, the wettability can be changed in the energy irradiated portion so as to generated a large wettability difference from the energy unirradiated portion. Therefore, adhesion of the organic EL layer forming coating solution onto the liquid repellent region, which is the energy unirradiated portion, can be prevented so that a highly precise organic EL layer pattern can be formed by adhering the organic EL layer forming coating solution only onto the lyophilic region, which is the energy irradiated portion.

Moreover, since the organic EL layer is patterned, utilizing the wettability changed pattern formed on the charge injecting and transporting layer, the organic EL layer can be patterned easily without a complicated patterning step or expensive vacuum equipment.

Furthermore, in this aspect, by the pattern irradiation of the energy to the charge injecting and transporting layer via the photocatalyst processing layer containing the photocatalyst, the wettability can be changed by the action of the photocatalyst with respect to the charge injecting and transporting layer which does not containing the photocatalyst. Moreover, since the photocatalyst processing layer substrate having the photocatalyst processing layer is detached from the charge injecting and transporting layer after the formation of the wettability changed pattern on the charge injecting and transporting layer surface, the photocatalyst is not contained in the charge injecting and transporting layer. Therefore, the smoothness of the charge injecting and transporting layer can be improved so that the obstacles present at the interface between the charge injecting and transporting layer and the organic EL layer can be reduced. Thereby, the light emission characteristics can be improved to prevent short circuit between the electrodes.

Moreover, the charge injecting and transporting function of the charge injecting and transporting layer may be improved by the energy irradiation to the charge injecting and transporting layer. Therefore, this aspect is particularly useful for patterning the organic EL layer.

Since the wettability changed pattern forming step, the organic EL layer forming step, the insulation layer forming step, the counter electrode layer forming step, or the like are same as in the above-mentioned item of the first embodiment, the explanation is omitted. Hereafter, the charge injecting and transporting layer forming step and the liquid repellent process step will be explained.

### (1) Charge Injecting and Transporting Layer Forming Step

The charge injecting and transporting layer forming step in this aspect is a step of forming a charge injecting and transporting layer on the substrate with the electrode layer formed.

Since the electrode layer and the substrate are same as in the item of the first embodiment, the explanation is omitted. Hereafter, the charge injecting and transporting layer will be explained.

(i) Charge Injecting and Transporting Layer

As the charge injecting and transporting layer in this embodiment, there are a hole injecting and transporting layer for stably injecting and transporting the hole into the light emitting layer, and an electron injecting and transporting layer for stably injecting and transporting the electron into the light emitting layer. In general, the electrode layer is provided as an anode in many cases, and in this case the charge injecting and transporting layer is provided as a hole injecting and transporting layer.

Hereafter, the hole injecting and transporting layer and the electron injecting and transporting layer will be explained separately.

### (Hole Injecting and Transporting Layer)

The hole injecting and transporting layer in this embodiment may be: a hole injecting layer having a hole injecting function of injecting the hole injected from the anode stably into the light emitting layer; a hole transporting layer having a hole transporting function of transporting the hole injected from the anode into the light emitting layer; a lamination of the hole injecting layer and the hole transporting layer; or a single layer having both the hole injecting function and the hole transporting function.

The material used for the hole injecting and transporting layer is same as the one described in the above-mentioned item of the hole injecting and transporting layer of the first embodiment, and the method for forming the hole injecting and transporting layer is same as the item of the hole injecting and transporting layer of the first embodiment. Thus, the explanations are omitted.

The film thickness of the hole injecting and transporting layer is not particularly limited as long as it is capable of sufficiently performing its function and capable of realizing the liquid repellent properties by introducing fluorine in the liquid repellent process step. Specifically, the film thickness of the hole injecting and transporting layer is preferably in the range of 5 nm to 300 nm, and particularly preferably in the range of 5 nm to 100 nm.

Since the method for forming the hole injecting and transporting layer is same as the item of the first embodiment, the explanation is omitted.

### (Electron Injecting and Transporting Layer)

The electron injecting and transporting layer in this aspect may be: an electron injecting layer having an electron injecting function of stably injecting the electron injected from the cathode into the light emitting layer; an electron transporting layer having an electron transporting function of transporting the electron injected form the cathode into the light emitting layer; a lamination of the electron injecting layer and the electron transporting layer; or a single layer having both the electron injecting function and the electron transporting function.

The material used for the electron injecting layer is same as the item of the electron injecting and transporting layer of the first embodiment, the material used for the electron transporting layer is same as the item of the electron injecting and transporting layer of the first embodiment, and the material used for the single layer having both the electron injecting function and the electron transporting function is same as the material having both the electron injecting properties and the electron transporting properties described in the item of the electron injecting and transporting layer of the first embodiment. Thus, the explanations are omitted.

The film thickness of the electron injecting and transporting layer is not particularly limited as long as it is capable of sufficiently performing its function and capable of realizing the liquid repellent properties by introducing the fluorine in the liquid repellent process step. Specifically, the film thickness of the electron injecting layer is in the range of 0.2 nm to 50 nm, more preferably in the range of 0.2 nm to 20 nm, and further preferably in the range of 0.2 nm to 10 nm. The film thickness of the electron transporting layer is in the range of 5 nm to 100 nm. The film thickness of the single layer having both the electron injecting function and the electron transporting function is preferably in the range of 5 nm to 1,000 nm, and more preferably in the range of 10 nm to 100 nm.

Since the method for forming the electron injecting and transporting layer is same as the above-mentioned item of the first embodiment, the explanation is omitted.

### (2) Liquid Repellent Process Step

The liquid repellent process step in this aspect is a step of processing the charge injecting and transporting layer surface to be liquid repellent by inducing the plasma using a fluorine compound as the introduction gas to the charge injecting and transporting layer.

The method for inducing the plasma is not particularly limited as long as it is a method for inducing the plasma using the fluorine compound as the introduction gas for processing the charge injecting and transporting layer surface to be liquid repellent. Thus, the plasma induction can be carried out under a reduced pressure under an atmospheric pressure.

As examples of the fluorine compound used as the introduction gas at the time of the plasma induction, carbon fluoride (CF₄), fluorine nitride (NF₃), sulfur fluoride (SF₆), CHF₃, C₂F₆, C₃F₈, or C₅F₈ can be presented.

Moreover, the plasma induction conditions can be selected optionally according to the induction device, or the like.

In this aspect, it is preferable that the plasma induction is the plasma induction in an atmospheric pressure because it is advantageous in terms of such as the cost, and the production efficiency for not requiring additional device such as a device for the pressure reduction. As the atmospheric plasma induction conditions, the following can be presented. For example, as the power source output, common plasma induction devices can be used. At the time, the distance between the electrode for the plasma to be induced and the charge injecting and transporting layer is about 0.2 mm to 20 mm, in particular, about 1 mm to 5 mm. Furthermore, the flow rate of the fluorine compound to be used as the introduction gas is preferably about 1 L/min to 20 L/min. The flow rate of the nitrogen gas to be supplied simultaneously with the fluorine compound is preferably about 1 L/min to 50 L/min. The substrate conveyance rate at the time is preferably about 0.5 m/min to 2 m/min.

The presence of the fluorine introduced into the charge injecting and transporting layer can be confirmed by measuring the ratio of the fluorine element in the entire elements to be detected form the surface of the charge injecting and transporting layer by the analysis with the X-ray photoelectron spectroscope (XPS: ESCALAB 220i-XL) used for the X-ray photoelectron spectroscopy (also referred to as the ESCA). At the time, the ratio of the fluorine to be introduced into charge injecting and transporting layer is preferably 10% or more out of the total elements to be detected.

Moreover, it is preferable that the plasma induction is carried out to the charge injecting and transporting layer so as to have the contact angle with respect to a liquid having the surface tension equivalent to the surface tension of the organic EL layer forming coating solution, to be applied in the organic EL layer forming step, made higher than the contact angle with respect to the liquid of the charge injecting and transporting layer before the liquid repellent process step by 1° or more. In particular, it is preferable that the plasma induction is carried out to the charge injecting and transporting layer so as to have a contact angle with respect to the liquid of 30° or more, in particular, 40° or more, and furthermore, 50° or more. In the case the contact angle with respect to the liquid of the charge injecting and transporting layer after the liquid repellent process step is small, the liquid repellent properties is insufficient so that the organic EL layer forming coating solution may be adhered also onto the liquid repellent region in the organic EL layer forming step.

The method for measuring the contact angle with respect to a liquid is same as in the item of the first embodiment.

### (3) Wettability Changed Pattern Forming Step

The wettability changed pattern forming step in this aspect is a step of forming a wettability changed pattern with the wettability changed on the charge injecting and transporting layer surface by the energy irradiation in pattern after disposing a photocatalyst processing layer substrate having at least a photocatalyst processing layer, which contains a photocatalyst formed on a base member, with a gap capable of providing the effect of the photocatalyst accompanied by the energy irradiation to the charge injecting and transporting layer with the liquid repellent process applied.

In this aspect, by removing the fluorine introduced into the charge injecting and transporting layer in the liquid repellent process step by the action of the photocatalyst accompanied by the energy irradiation, the energy irradiated portion can be provided as lyophilic and the energy unirradiated portion as liquid repellent.

In the lyophilic region which is the energy irradiated portion, the contact angle with respect to a liquid having the surface tension equivalent to the surface tension of the organic EL layer forming coating solution to be applied after removing the fluorine introduced into the charge injecting and transporting layer is preferably 30° or less, more preferably 20° or less, and further preferably 10° or less. If the contact angle with respect to a liquid in the lyophilic region which is the energy irradiated portion is too high, the organic EL layer forming coating solution may hardly be spread so that the organic EL layer may be lacked, or the like.

The method for measuring the contact angle with respect to a liquid is same as in the item of the first embodiment.

Moreover, the photocatalyst processing layer substrate, the energy irradiation, and the arrangement of the photocatalyst processing layer substrate and the charge injecting and transporting layer, or the like are same as in the item of the first embodiment. Thus, the explanations are omitted.

### 2. Second Aspect

The second aspect of the manufacturing method of an organic EL element of the present embodiment comprises: a charge injecting and transporting layer forming step of forming a charge injecting and transporting layer on a substrate with an electrode layer formed; a liquid repellent process step of processing the charge injecting and transporting layer surface to be liquid repellent by forming on the charge injecting and transporting layer a wettability changes layer whose wettability changed by the action of the photocatalyst accompanied by the energy irradiation; a wettability changed pattern forming step of forming a wettability changed pattern with the wettability changed on the charge injecting and transporting layer surface by the energy irradiation in pattern after disposing a photocatalyst processing layer substrate surface, in which a photocatalyst processing layer containing at least a photocatalyst formed on a base member, with a gap capable of providing the action of the photocatalyst accompanied by the energy irradiation to the charge injecting and transporting layer with the liquid repellent process applied; and an organic EL layer forming step of forming an organic EL layer including at least a light emitting layer on the wettability changed pattern.

The manufacturing method of an organic EL element of the aspect will be explained with reference to the drawings.

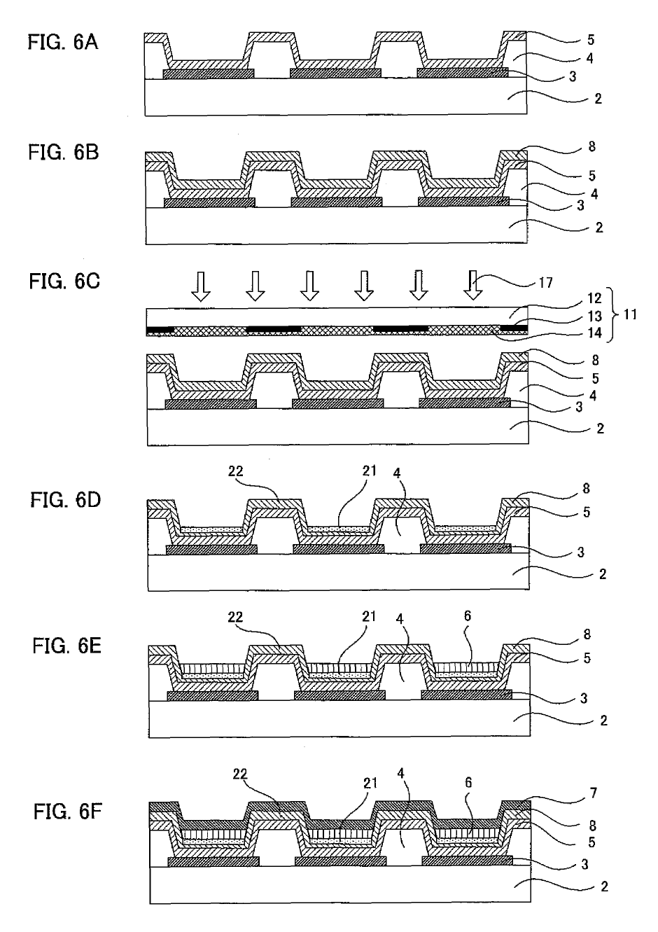

FIGS. 6A to 6F are process drawings showing an example of an organic EL element of this aspect. First, the electrode layers 3 are formed in pattern on the substrate 2, the insulation layer 4 is formed between patterns of the electrode layer 3, the charge injecting and transporting layer 5 is formed on the electrode layer 3 and insulation layer 4 (FIG. 6A, the charge injecting and transporting layer forming step). Next, wettability changed layer 8 is formed on the charge injecting and transporting layer (FIG. 6B, the light repellent process step). Accordingly, the surface of the charge injecting and transporting layer 5 becomes liquid repellent.

Next, as shown in FIG. 6C, a photocatalyst processing layer substrate 11 having a base member 12, light shielding parts 13 formed in pattern on the base member 12, and a photocatalyst processing layer 14 formed on the base member 12 so as to cover the light shielding part 13 is prepared. The photocatalyst processing layer 14 of the photocatalyst processing layer substrate 11 and the wettability changed layer 8 are disposed to face each other, and ultraviolet ray 17 is irradiated. According to the ultraviolet ray 17 irradiation, as shown in FIG. 6D, the ultraviolet ray irradiated portion out of the wettability changed layer 8 has the wettability change so as to have the contact angle with respect to a liquid lowered by the action of the photocatalyst contained in the photocatalyst processing layer 14. The region having the wettability change to lower the contact angle with respect to a liquid is referred to as a lyophilic region 21. In the ultraviolet ray unirradiated portion, the wettability is not changed. The region without the wettability change is referred to as a liquid repellent region 22. Then, the photocatalyst processing layer substrate 11 is detached from the wettability changed layer 8. Thereby, a wettability changed pattern having the lyophilic region 21 and the liquid repellent region 22 is formed on the wettability changed layer 8 surface. FIGS. 6C and 6D show the wettability changed pattern forming step.

The wettability changed layer 8 has the wettability change by the action of the photocatalyst accompanied by the energy irradiation, which has a wettability difference between the lyophilic region 21 which is the ultraviolet ray irradiated portion and the liquid repellent region 22 which is the ultraviolet ray unirradiated portion.

Next, utilizing the wettability difference, an organic EL layer 6 is formed on the lyophilic region 21 by applying the organic EL layer forming coating solution on the wettability changed pattern having the lyophilic region 21 and the liquid repellent region 22 (FIG. 6E, organic EL layer forming step).

Then, a counter electrode layer 7 is formed on the organic EL layer 6 (FIG. 6F). At the time, if the counter electrode layer 7 is provided as a transparent electrode, an organic EL element of the top emission type can be obtained, and if the electrode layer 3 is provided as a transparent electrode, an organic EL element of the bottom emission type can be obtained.

In this aspect, the charge injecting and transporting layer surface is processed to be liquid repellent by forming the wettability changed layer in the liquid repellent process step. The wettability changed layer is to have the wettability change by the action of the photocatalyst accompanied by the energy irradiation so that the wettability changed pattern is formed by the wettability difference on the wettability changed layer surface, that is, the charge injecting and transporting layer surface by the energy irradiation via the photocatalyst processing layer containing the photocatalyst to the wettability changed layer. Then, the organic EL layer is patterned, utilizing the wettability changed pattern. Therefore, the organic EL layer can be patterned easily without a complicated patterning step or expensive vacuum equipment.

Moreover, in this aspect, the wettability can be changed by the action of the photocatalyst with respect to the wettability changed layer, which does not containing the photocatalyst, by the pattern irradiation of the energy to the wettability changed layer via the photocatalyst processing layer which contains the photocatalyst. Moreover, since the photocatalyst processing layer substrate containing the photocatalyst processing layer is detached form the wettability changed layer after the formation of the wettability changed pattern on the wettability changed layer surface, the photocatalyst is not contained in the wettability changed layer. Therefore, the smoothness of the wettability changed layer can be improved so that the obstacles present at the interface between the charge injecting and transporting layer and the wettability changed layer and the interface between the wettability changed layer and the organic EL layer can be reduced. Thereby, the light emission characteristics can be improved and short circuit between the electrodes can be prevented.

The charge injecting and transporting layer forming step is same as in the first aspect, and the organic EL layer forming step, the insulation layer forming step and the counter electrode layer forming step are same as in the item of the first aspect. Thus, the explanations are omitted. Hereafter, the liquid repellent process step and the wettability changed pattern forming step will be explained.

### (1) Liquid Repellent Process Step

The liquid repellent process step in this embodiment is a step of processing the charge injecting and transporting layer surface to be liquid repellent by forming on the charge injecting and transporting layer a wettability changed layer whose wettability changes by the action of the photocatalyst accompanied by the energy irradiation.

The wettability changed layer used in this aspect has the wettability change by the action of the photocatalyst accompanied by the energy irradiation.

The wettability changed layer is not particularly limited as long as it contains a material whose wettability changes by the action of the photocatalyst. Since the material whose wettability changes by the action of the photocatalyst is same as the liquid repellent material in the item of the charge injecting and transporting layer of the first embodiment, the explanation is omitted.

Moreover, the wettability changed layer may contain the surfactant, the oligomer or the polymer described in the item of the photocatalyst processing layer of the first embodiment.

The film thickness of the wettability changed layer is not particularly limited as long as it is capable of forming the wettability changed pattern without inhibiting the transportation of the hole or the electron. Specifically, the film thickness of the wettability changed layer is preferably 20 nm or less, and particularly preferably in the range of 1 nm to 15 nm. This is because the film thickness of the wettability changed layer is in the above-mentioned range, the charge can be tunnel-injected by the external electric field.

As the method for forming the wettability changed layer, a method of applying the wettability changed layer forming coating solution on the charge injecting and transporting layer can be used.

The wettability changed layer forming coating solution can be prepared by dissolving or dispersing in a solvent such as the material whose wettability changes by the action of the photocatalyst.

The solvent to be used at the time is not particularly limited as long as it can be mixed with the material ehose wettability change by the action of the photocatalyst without influencing the patterning characteristics by opaqueness or other phenomena. As examples of such a solvent, alcohols such as methanol, ethanol, isopropanol; and butanol, acetone, acetonitrile, ethylene glycol monomethyl ether, ethylene glycol dimethyl ether, ethylene glycol monoethyl ether, ethylene glycol monoethyl ether acetate, diethyl glycol monomethyl ether, diethyl glycol monoethyl ether, diethyl glycol monoethyl ether acetate, propylene glycol monomethyl ether, propylene glycol monoethyl ether, propylene glycol monomethyl ether acetate, methyl acetate, ethyl acetate, butyl acetate, toluene, xylene, methyl lactate, ethyl lactate, ethyl pyruvate, 3-methyl methoxy propionate, 3-ethyl ethoxy propionate, dimethyl formamide, dimethyl sulfoxide, dioxane, ethylene glycol, triamide hexamethyl phosphate, pyridine, tetrahydrofuran, or N-methyl pyrolidinone can be presented. These solvents may be used as a mixture of two or more kinds.

As the method for applying the wettability changed layer forming coating solution, a spin coating method, an ink jet method, a casting method, a LB method, a dispenser method, a micro gravure coating method, a gravure coating method, a bar coating method, a roll coating method, a wire bar coating method, a dip coating method, a flexo printing method, an offset printing method, or a screen printing method can be presented as examples.

After the application of the wettability changed layer forming coating solution, the coating film may be dried. The drying method is not particularly limited as long as an even wettability changed layer can be formed. For example, a hot plate, an infrared heater, or an oven can be used.

### (2) Wettability Changed Pattern Forming Step

The wettability changed pattern forming step in this aspect is a step of forming a wettability changed pattern with the wettability changed on the charge injecting and transporting layer surface by the energy irradiation in pattern after disposing a photocatalyst processing layer substrate having at least a photocatalyst processing layer, which contains a photocatalyst formed on a base member, with a gap capable of providing the effect of the photocatalyst accompanied by the energy irradiation to the charge injecting and transporting layer with the liquid repellent process applied.

In this embodiment, the wettability changed layer is formed on the charge injecting and transporting layer in the liquid repellent process step. Therefore, in this embodiment, “to dispose the photocatalyst processing layer substrate with a predetermined gap provided to the charge injecting and transporting layer” denotes to dispose the photocatalyst processing layer substrate with a predetermined gap provided to the wettability changed layer. That is, in general, the photocatalyst processing layer of the photocatalyst processing layer substrate and the wettability changed layer are disposed with a gap capable of providing the action of the photocatalyst accompanied by the energy irradiation to the wettability changed layer.

Since the arrangement of the photocatalyst processing layer substrate and the wettability changed layer is same as the arrangement of the photocatalyst processing layer substrate and the charge injecting and transporting layer in the item of the first embodiment, the explanation is omitted.

The photocatalyst processing layer substrate, the energy irradiation and the wettability changed pattern are same as in the item of the first embodiment, the explanation a are omitted.

The present invention is not limited to the above-mentioned embodiments. The embodiments are merely examples, and any one having the substantially same configuration as the technological idea disclosed in the claims of the present invention and the same effects is included in the technological scope of the present invention.

### EXAMPLES

Hereinafter, the present invention will be explained specifically with reference to the examples and the comparative examples.

### Example 1

### (Formation of the Electrode Layer and the Insulation Layer)

First, a substrate comprising a glass substrate having an ITO film as the electrode layer formed in pattern of an 80 μm line width, a 20 μm space width and a 100 μm pitch was prepared.

Then, an insulation film was formed on the entire surface of the above-mentioned substrate by applying a positive type photosensitive material (OFPR-800, produced by Tokyo Ohka Kogyo Co., Ltd.) by the spin coating method so as to have a 1.5 μm film thickness. Then, exposure was carried out using a photo mask having a rectangular opening part of a 70 μm lateral width and a 70 μm longitudinal width, and development was executed with an alkaline developing solution (NMD-3, Tokyo Ohka Kogyo Co., Ltd.). Subsequently, by the heat curing process was carried out at 250° C. for 30 minutes, an insulation layer was formed in the opening part of the electrode layer.

### (Formation of the Hole Injecting Layer)

A hole injecting layer forming coating solution was prepared by mixing a tridecafluorooctyl trimethoxy silane having fluorine at the end (TSL8257, produced by GE Toshiba Silicones) diluted with isopropyl alcohol as the liquid repellent material to an aqueous solution of a poly(3,4-alkene dioxythiophene) and a base of a polystyrene sulfonic acid (PEDOT/PSS) (Baytron P CH-8000, produced by H. C. Stark Inc.). A hole injecting layer was formed by applying the hole injecting layer forming coating solution onto the above-mentioned substrate by the spin coating method so as to have a film thickness after drying of 80 nm.

### (Preparation of the Photocatalyst Processing Layer Substrate)

A photo mask having light shielding parts formed in pattern on a base member and a rectangular opening part of a 85 μm lateral width and a 85 μm longitudinal width was prepared. A photocatalyst processing layer forming coating solution of the following composition was applied on the photo mask by a spin coater, and a heat drying process was carried out at 150° C. for 10 minutes for promoting the hydrolysis-polycondensation reaction for curing so as to form a 2,000 Å film thickness transparent photocatalyst processing layer, in which the photocatalyst is firmly fixed in the organosiloxane.

### <Photocatalyst Processing Layer Forming Coating Solution>

| | | |
|---|---|---|
| Titanium dioxide (ST-K01, produced by Ishihara | 2 | parts by mass |
| Sangyo Kaisha, Ltd.) | | |
| Organoalkoxy silane (TSL8113 produced by | 0.4 | part by mass |
| Toshiba Silicones) | | |
| Fluoroalkyl silane (MF-160E produced by Tohkem | 0.3 | part by mass |
| Products Co., Ltd) | | |
| Isopropyl alcohol | 3 | parts by mass |

### (Formation of the Wettability Changed Pattern)

The positions of the opening part of the photocatalyst processing layer substrate and the pattern of the electrode layers of the above-mentioned substrate were adjusted using a high pressure mercury lamp and a ultraviolet ray exposing device comprising the photocatalyst processing layer substrate and a position adjusting mechanism for a substrate. After adjusting the distance between the photocatalyst processing layer of the photocatalyst processing layer substrate and the hole injecting layer to 20 μm, exposure was carried out from the rear surface side of the photocatalyst processing layer substrate by a 200 mJ/cm² exposure amount of a 253 nm light beam.

The contact angle with respect to a liquid was measured with a contact angle meter (produced by Kyowa Interface Science Co., LTD.) in the exposed portion and the unexposed portion of the surface of the hole injecting layer.

### (Formation of the Organic EL Layer)

Light emitting layer forming coating solutions of each color with the following composition was prepared.

### <Red Light Emitting Layer Forming Coating Solution>

| | | |
|---|---|---|
| Polyvinyl carbazol | 7 | parts by weight |
| Nile Red | 0.1 | part by weight |
| Oxadiazol compound | 3 | parts by weight |
| Tetralin | 990 | parts by weight |

### <Green Light Emitting Layer Forming Coating Solution>

| | | |
|---|---|---|
| Polyvinyl carbazol | 7 | parts by weight |
| Coumarin 6 | 0.1 | part by weight |
| Oxadiazol compound | 3 | parts by weight |
| Tetralin | 990 | parts by weight |

### <Blue Light Emitting Layer Forming Coating Solution>

| | | |
|---|---|---|
| Polyvinyl carbazol | 7 | parts by weight |
| Perylene | 0.1 | part by weight |
| Oxadiazol compound | 3 | parts by weight |
| Tetralin | 990 | parts by weight |

The viscosity of the above-mentioned light emitting layer forming coating solutions of each color was 12 mPa·s, and the surface tension was 35 dyn/cm. By applying these light emitting layer forming coating solutions onto the lyophilic region by the ink jet method and drying at 130° C. for 1 hour in a nitrogen, light emitting layers of R, G, B were formed in pattern. Thereafter, the light emitting layers were observed with a fluorescence microscope.

### (Production of the Organic EL Element)

As a counter electrode layer, Ca was formed by 1,000 A and Al by 2,000 Å on the substrate with the light emitting layer formed with a vacuum deposition device.

A light emitting state was examined by applying a direct current with a source meter while the electrode layer side connected to a positive pole and the counter electrode layer side connected to a negative pole.

### Example 2

An organic EL element was produced in the same manner as in the example 1 except that the preparation of the photocatalyst processing layer substrate and the formation of the wettability changed pattern were carried out as follows.

### (Preparation of the Photocatalyst Processing Layer Substrate)

The same photocatalyst processing layer forming coating solution as in the example 1 was applied on a quartz substrate by a spin coater, and a heat drying process was carried out at 150° C. for 10 minutes for promoting the hydrolysis-polycondensation reaction for curing so as to form a 2,000 Å film thickness transparent photocatalyst processing layer, in which the photocatalyst firmly fixed in the organosiloxane.

### (Formation of the Wettability Changed Pattern)

After adjusting the distance between the photocatalyst processing layer of the photocatalyst processing layer substrate and the hole injecting layer to 20 μm, exposure was carried out from the rear surface side of the substrate using a high pressure mercury lamp by a 300 mJ/cm exposure amount of a 253 nm light beam.

The contact angle with respect to a liquid was measured with a contact angle meter (produced by Kyowa Interface Science Co., LTD.) in the exposed portion and the unexposed portion of the surface of the hole injecting layer.

### Example 3

An organic EL element was produced in the same manner as in the example 1 except that the formation of the hole injecting layer, the formation of the wettability changed layer and the formation of the wettability changed pattern were carried out as follows.

### (Formation of the Hole Injecting Layer)

A hole injecting layer forming coating solution was prepared by mixing a γ-glycidoxy trimethoxy silane having a glycid group (—CHOCH₂) (TSL8350, produced by Toshiba Silicones) to an aqueous solution of a poly(3,4-alkene dioxythiophene) and a base of a polystyrene sulfonic acid (PEDOT/PSS) (Baytron P CH-8000, produced by H. C. Stark Inc.). At the time, the γ-glycidoxy trimethoxy silane was added by a 10% ratio with respect to the solid component of the aqueous solution of the PEDOT/PSS.

Next, a hole injecting layer was formed by applying the hole injecting layer forming coating solution onto the substrate with the insulation layer formed by the spin coating method so as to have a film thickness after drying of 80 nm, and carrying out a heat drying process at 150° C. for 15 minutes.

### (Formation of the Wettability Changed Layer)

A wettability changed layer forming coating solution was prepared by diluting a tridecafluorooctyl trimethoxy silane having fluorine at the end (TSL8257, produced by GE Toshiba silicones) with an isopropyl alcohol. A wettability changed layer was formed by applying the wettability changed layer forming coating solution onto the above-mentioned hole injecting layer by the spin coating method so as to have the film thickness after drying of 10 nm, and drying.

### (Formation of the Wettability Changed Pattern)

After adjusting the distance between the photocatalyst processing layer of the photocatalyst processing layer substrate and the wettability changed layer to 20 μm, exposure was carried out from the rear surface side of the substrate by a 300 mJ/cm² exposure amount of a 253 nm light beam using a high pressure mercury lamp.

The contact angle with respect to a liquid was measured with a contact angle meter (produced by Kyowa Interface Science Co., LTD.) in the exposed portion and the unexposed portion of the surface of the wettability changed layer.

### Comparative Example 1

An organic EL element was produced in the same manner as in the example 1 except that a base member with light shielding parts formed in pattern and a photo mask having a rectangular opening part of an 85 μm lateral width and an 85 μm longitudinal width was used instead of the photocatalyst processing layer substrate.

### Comparative Example 2

An organic EL element was produced in the same manner as in the example 2 except that a base member with light shielding parts formed in pattern and a photo mask having a rectangular opening part of an 85 μm lateral width and an 85 μm longitudinal width was used instead of the photocatalyst processing layer substrate.

### Comparative Example 3

An organic EL element was produced in the same manner as in the example 3 except that a base member with light shielding parts formed in pattern and a photo mask having a rectangular opening part of an 85 μm lateral width and an 85 μm longitudinal width was used instead of the photocatalyst processing layer substrate.

### Example 4

An organic EL element was produced in the same manner as in the example 1 except that the liquid repellent process of the hole injecting layer was carried out as follows before the formation of the wettability changed pattern.

### (Liquid Repellent Process of the Hole Injecting Layer)

The hole injecting layer surface was processed to be liquid repellent by carrying out the plasma process using carbon fluoride (CF₄) as the introduction gas. At the time, the plasma process was carried out for 60 seconds to 3,600 seconds, using the CF₄ by the conditions of the gas flow rate: 90 to 900 SCCM, the power: 0.1 W/cm² to 1.0 W/cm², and the pressure: 1 Torr or less. Thereby, the surface energy of the hole injecting layer was lowered.

### [Evaluation]

The wettability evaluation, the light emitting layer observation results and the light emission states in the examples 1 to 4 and the comparative examples 1 to 3 are shown in the following table 1.

TABLE 1

| | Contact | Contact | | |
|---|---|---|---|---|
| | angle in the | angle in the | Patterning of | Light |
| | exposed | unexposed | the light | emission |
| | portion (°) | portion (°) | emitting layer | state |
| Example 1 | <10 | 60 | good | good |
| Example 2 | <10 | 60 | good | good |
| Example 3 | <10 | 60 | good | good |
| Example 4 | <10 | 60 | good | good |
| Comparative | 60 | 60 | Poor | No light |
| example 1 | | | | emission |
| Comparative | 60 | 60 | Poor | No light |
| example 2 | | | | emission |
| Comparative | 60 | 60 | Poor | No light |
| example 3 | | | | emission |

What is claimed is:

1. A manufacturing method of an organic electroluminescence element comprising:
a charge injecting and transporting layer forming step of forming, on a substrate with an electrode layer formed, a charge injecting and transporting layer containing a material having a liquid repellent functional group so as to have a wettability change by an action of a photocatalyst accompanied by energy irradiation;
a wettability changed pattern forming step of forming a wettability changed pattern with wettability changed on a surface of the charge injecting and transporting layer by the energy irradiation in pattern after disposing a photocatalyst processing layer substrate, in which a photocatalyst processing layer containing at least a photocatalyst is formed on a base member, with a gap capable of providing the action of the photocatalyst accompanied by the energy irradiation to the charge injecting and transporting layer; and
an organic electroluminescence layer forming step of forming an organic electroluminescence layer, which includes at least a light emitting layer, on the wettability changed pattern.

2. The manufacturing method of an organic electroluminescence element according to claim 1, wherein the material having the liquid repellent functional group is a liquid repellent material, and the charge injecting and transporting layer further contains a charge injecting and transporting material having charge injecting and transporting properties.

3. The manufacturing method of an organic electroluminescence element according to claim 1, wherein the material having the liquid repellent functional group is a single material having a portion with charge injecting and transporting properties and a portion with the liquid repellent functional group.

4. The manufacturing method of an organic electroluminescence element according to claim 1, wherein the liquid repellent functional group contains fluorine.

5. The manufacturing method of an organic electroluminescence element according to claim 2, wherein the liquid repellent functional group contains fluorine.

6. The manufacturing method of an organic electroluminescence element according to claim 3, wherein the liquid repellent functional group contains fluorine.

7. A manufacturing method of an organic electroluminescence element comprising:
a charge injecting and transporting layer forming step of forming a charge injecting and transporting layer on a substrate with an electrode layer formed;
a liquid repellent process step of processing a surface of the charge injecting and transporting layer to be liquid repellent;
a wettability changed pattern forming step of forming a wettability changed pattern with wettability changed on a surface of the charge injecting and transporting layer by energy irradiation in pattern after disposing a photocatalyst processing layer substrate, in which a photocatalyst processing layer containing at least a photocatalyst is formed on a base member, with a gap capable of providing an action of the photocatalyst accompanied by the energy irradiation to the charge injecting and transporting layer with the liquid repellent process applied; and
an organic electroluminescence layer forming step of forming an organic electroluminescence layer, which includes at least a light emitting layer, on the wettability changed pattern.

8. The manufacturing method of an organic electroluminescence element according to claim 7, wherein the liquid repellent process step is a step of inducing plasma using a fluorine compound as an introduction gas to the charge injecting and transporting layer.

9. The manufacturing method of an organic electroluminescence element according to claim 1, wherein the charge injecting and transporting layer is a hole injecting and transporting layer.

10. The manufacturing method of an organic electroluminescence element according to claim 2, wherein the charge injecting and transporting layer is a hole injecting and transporting layer.

11. The manufacturing method of an organic electroluminescence element according to claim 3, wherein the charge injecting and transporting layer is a hole injecting and transporting layer.

12. The manufacturing method of an organic electroluminescence element according to claim 7, wherein the charge injecting and transporting layer is a hole injecting and transporting layer.

13. The manufacturing method of an organic electroluminescence element according to claim 8, wherein the charge injecting and transporting layer is a hole injecting and transporting layer.

14. The manufacturing method of an organic electroluminescence element according to claim 1, wherein an insulation layer forming step of forming an insulation layer, for reflecting or absorbing energy line to be irradiated in the wettability changed pattern forming step, between patterns of the electrode layer formed on the substrate with the electrode layer formed in pattern is carried out before the charge injecting and transporting layer forming step.

15. The manufacturing method of an organic electroluminescence element according to claim 2, wherein an insulation layer forming step of forming an insulation layer, for reflecting or absorbing energy line to be irradiated in the wettability changed pattern forming step, between patterns of the electrode layer formed on the substrate with the electrode layer formed in pattern is carried out before the charge injecting and transporting layer forming step.

16. The manufacturing method of an organic electroluminescence element according to claim 3, wherein an insulation layer forming step of forming an insulation layer, for reflecting or absorbing energy line to be irradiated in the wettability changed pattern forming step, between patterns of the electrode layer formed on the substrate with the electrode layer formed in pattern is carried out before the charge injecting and transporting layer forming step.

17. The manufacturing method of an organic electroluminescence element according to claim 7, wherein an insulation layer forming step of forming an insulation layer, for reflecting or absorbing energy line to be irradiated in the wettability changed pattern forming step, between patterns of the electrode layer formed on the substrate with the electrode layer formed in pattern is carried out before the charge injecting and transporting layer forming step.

18. The manufacturing method of an organic electroluminescence element according to claim 8, wherein an insulation layer forming step of forming an insulation layer, for reflecting or absorbing energy line to be irradiated in the wettability changed pattern forming step, between patterns of the electrode layer formed on the substrate with the electrode layer formed in pattern is carried out before the charge injecting and transporting layer forming step.
